(19) United States
(12) Patent Application Publication
(10) Pub. No.: US 2026/0105626 A1
(43) Pub. Date: Apr. 16, 2026

(54) EDGE LOCALIZATION VIA INTELLIGENT INSERTION OF IMAGE PROCESSING CALIPERS

(71) Applicant: FEI Company, Hillsboro, OR (US)

(72) Inventors: Remco Geurts, Nuenen (NL); Pavel Potocek, Eindhoven (NL)

(21) Appl. No.: 18/913,069

(22) Filed: Oct. 11, 2024

(51) Int. Cl. G06T 7/73; G06T 5/20; G06T 5/70; G06T 7/12

(52) U.S. Cl. CPC G06T 7/73; G06T 5/20; G06T 5/70; G06T 7/12; G06T 2207/10061; G06T 2207/20016; G06T 2207/20081; G06T 2207/20084

(57) ABSTRACT

Systems/techniques are provided for facilitating edge localization via intelligent insertion of image processing calipers. In various embodiments, a system can access an image captured by a charged-particle microscope, wherein the image depicts a specimen. In various aspects, the system can localize, via execution of a deep learning neural network on the image, an approximate boundary of a structure of interest of the specimen. In various instances, the system can localize a true boundary of the structure of interest, based on placing a plurality of image processing calipers along the approximate boundary.

### BACKGROUND

When given an image captured by a charged-particle microscope, localizing edges of a structure of interest in that image can be difficult.

### SUMMARY

The following presents a summary to provide a basic understanding of one or more embodiments. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus or computer program products that facilitate edge localization via intelligent insertion of image processing calipers are described.

According to one or more embodiments, a system is provided. The system can comprise a non-transitory computer-readable memory that can store computer-executable components. The system can further comprise a processor that can be operably coupled to the non-transitory computer-readable memory and that can execute the computer-executable components stored in the non-transitory computer-readable memory. In various embodiments, the computer-executable components can comprise an access component that can access an image captured by a charged-particle microscope, wherein the image depicts a specimen. In various aspects, the computer-executable components can comprise a coarse component that can localize, via execution of a deep learning neural network on the image, an approximate boundary of a structure of interest of the specimen. In various instances, the computer-executable components can comprise a fine component that can localize a true boundary of the structure of interest, based on placing a plurality of image processing calipers along the approximate boundary.

According to one or more embodiments, a computer-implemented method is provided. In various embodiments, the computer-implemented method can comprise accessing, by a device operatively coupled to a processor, an image captured by a charged-particle microscope, wherein the image depicts a specimen. In various aspects, the computer-implemented method can comprise localizing, by the device and via execution of a deep learning neural network on the image, an approximate boundary of a structure of interest of the specimen. In various instances, the computer-implemented method can comprise localizing, by the device, a true boundary of the structure of interest, based on placing a plurality of image processing calipers along the approximate boundary.

According to one or more embodiments, a computer program product for facilitating edge localization via intelligent insertion of image processing calipers is provided. In various embodiments, the computer program product can comprise a non-transitory computer-readable memory having program instructions embodied therewith. In various aspects, the program instructions can be executable by a processor to cause the processor to instruct a charged-particle microscope to capture a scanned image of a specimen. In various instances, the program instructions can be executable to cause the processor to execute a deep learning edge localizer on the scanned image, thereby yielding a first localization that indicates where in the scanned image a boundary of a structure of interest of the specimen is inferred to be. In various cases, the program instructions can be executable to cause the processor to generate a second localization that indicates, with higher accuracy than the first localization, where in the scanned image the boundary is, based on placing along the first localization a plurality of image processing calipers that each detect a respective portion of the boundary by analyzing a respective pixel intensity profile that is substantially perpendicular to the first localization.

### DESCRIPTION OF THE DRAWINGS

Various embodiments will be readily understood by the following detailed description in conjunction with the accompanying figures. To facilitate this description, like reference numerals designate like structural elements. Embodiments are illustrated by way of example, not by way of limitation, in the figures. The figures are not necessarily drawn to scale.

FIG. 1 illustrates an example, non-limiting block diagram of a scientific instrument module in accordance with various embodiments described herein.

FIG. 2 illustrates an example, non-limiting flow diagram of a computer-implemented method in accordance with various embodiments described herein.

FIG. 3 illustrates a block diagram of an example, non-limiting system that facilitates edge localization via intelligent insertion of image processing calipers in accordance with one or more embodiments described herein.

FIG. 4 illustrates a block diagram of an example, non-limiting system including a scanned image that facilitates edge localization via intelligent insertion of image processing calipers in accordance with one or more embodiments described herein.

FIG. 5 illustrates an example, non-limiting block diagram showing how a scanned image can be obtained in accordance with one or more embodiments described herein.

FIG. 6 illustrates a block diagram of an example, non-limiting system including a deep learning neural network and a coarse boundary localization that facilitates edge localization via intelligent insertion of image processing calipers in accordance with one or more embodiments described herein.

FIG. 7 illustrates an example, non-limiting block diagram showing how a coarse boundary localization can be obtained in accordance with one or more embodiments described herein.

FIG. 8 illustrates a block diagram of an example, non-limiting system including a set of image processing calipers and a fine boundary localization that facilitates edge localization via intelligent insertion of image processing calipers in accordance with one or more embodiments described herein.

FIG. 9 illustrates an example, non-limiting block diagram showing how a set of image processing calipers can obtain a fine boundary localization in accordance with one or more embodiments described herein.

FIGS. 10-16 illustrate example, non-limiting dramatizations that clarify one or more embodiments described herein.

FIG. 17 illustrates an example, non-limiting block diagram showing how a deep learning neural network can be trained in accordance with one or more embodiments described herein.

FIG. 18 illustrates a block diagram of an example, non-limiting operating environment in which one or more embodiments described herein can be facilitated.

FIG. 19 illustrates an example networking environment operable to execute various implementations described herein.

FIG. 20 illustrates an example dual beam microscope that can be implemented in accordance with various embodiments described herein.

### DETAILED DESCRIPTION

The following detailed description is merely illustrative and is not intended to limit embodiments or application/uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiments.

Various additional operations can be performed, or described operations can be omitted in additional embodiments.

Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices. As used herein, the phrase “based on” should be understood to mean “based at least in part on,” unless otherwise specified.

A charged-particle microscope (e.g., a scanning electron microscope (SEM), a transmission electron microscope (TEM), a dual beam microscope) can be any suitable computerized device that can capture or generate microscopic or nanoscopic images of specimens in a scientific, laboratory, research, or clinical operational environment. To facilitate the capture or generation of such images, charged-particle microscopes can leverage complex arrangements of actuatable parts (e.g., ion sources, electron sources, optical lenses or apertures, optical plates or deflectors, columns, coils, heaters, coolers, fluid valves, fluid pumps, circuit switches, specimen stages), sensors (e.g., ion detectors, electron detectors, voltmeters, thermistors, potentiometers, pressure gauges), or consumables (e.g., carrier fluids, calibrants, filters, reactive gases).

A specimen (e.g., an integrated circuit chip, a semiconductor wafer, a lamella, a biological or organic sample), whether synthetic (e.g., fabricated or manufactured via any suitable photolithographic techniques such as etching or deposition) or naturally-occurring, can have or otherwise contain any suitable structure of interest (e.g., fin, gate, drain, nanowire, organelle, contaminant particle). An image of the specimen can be captured by a charged-particle microscope, and it can be desired to localize, via machine learning and within that image, a boundary or edge of the structure of interest. Once the boundary or edge of the structure of interest is localized, any suitable follow-on or downstream actions can then be taken (e.g., the localized boundary or edge can be transmitted to any downstream model or analytical process that treats as input the localized boundary or edge).

As the inventors of various embodiments described herein recognized, such boundary or edge localization can be considered as a difficult or non-trivial task.

Some existing techniques facilitate edge or boundary localization by using manually-placed image processing calipers. An image processing caliper can be a computer vision operation, algorithm, or technique that detects an edge or boundary along a straight line of pixels by analyzing (e.g., via derivative computations) the intensity profile of that straight line of pixels. In this way, an image processing caliper can thus be considered as a directional or anisotropic electronic tool that yields different results when placed in different positions or orientations within a given image (e.g., changing which straight line of pixels that an image processing caliper is applied to can change what, if any, edge or boundary is detected by the image processing caliper).

When such existing techniques are implemented for a scanned image produced by a charged-particle microscope, a user or technician manually views or inspects the scanned image and manually selects where to apply image processing calipers. In other words, such existing techniques involve the user or technician manually placing image processing calipers in the scanned image so as to detect which specific pixels belong to the edge or boundary of whatever structure of interest is desired. Although image processing calipers can achieve highly accurate edge or boundary localization, the requirement that they be manually placed by the user or technician can be considered as excessively restrictive and time-consuming. Indeed, it can take even experienced or well-trained users or technicians upwards of minutes to localize the boundary or edge of a single structure of interest by manually placing image processing calipers. Because various operational contexts in the real-world often involve hundreds, thousands, or even millions of scanned images that are queued for edge or boundary localization, such existing techniques can be considered as painfully slow and inadequate when deployed.

Other existing techniques facilitate edge or boundary localization by using deep learning. In particular, such other existing techniques involve training, in supervised fashion, a deep learning neural network to receive as input a scanned image captured by a charged-particle microscope and to produce as output a localization (e.g., segmentation mask) that indicates where the boundary or edge of a structure of interest is located within the scanned image. In other words, such other existing techniques involve training the deep learning neural network to visually recognize which pixels of the scanned image belong to or make up the boundary or edge of the structure of interest and which pixels do not. In contrast to manually-placed image processing calipers, the deep learning neural network can localize edges or boundaries in mere seconds, which can be considered as orders of magnitude faster than manually-placed image processing calipers. However, notwithstanding the deep learning neural network having undergone extensive training, it can be vulnerable to localization inaccuracy. For example, the deep learning neural network can be prone to overshooting the edges or boundaries of certain structures of interest (e.g., mistakenly inferring that a boundary or edge encompasses more area than it actually does) or to undershooting the edges or boundaries of other structures of interest (e.g., mistakenly inferring that an edge or boundary encompasses less area than it actually does).

In other words, existing techniques that rely upon deep learning can be considered as sacrificing accuracy for convenience, whereas existing techniques that instead rely upon manually-placed image processing calipers can be considered as sacrificing convenience for accuracy. Thus, all of such existing techniques can be considered as disadvantageous.

Accordingly, systems or techniques that can provide accurate edge or boundary localization in a non-time-consuming fashion can be desirable.

Various embodiments described herein can address this technical problem. One or more embodiments described herein can include systems, computer-implemented methods, apparatus, or computer program products that can facilitate edge localization via intelligent insertion of image processing calipers. In particular, the present inventors devised various techniques that involve utilizing both deep learning and image processing calipers to facilitate edge or boundary localization. Specifically, for any given image captured by a charged-particle microscope, various embodiments described herein can involve executing on the given image a deep learning neural network that has been trained to localize edges or boundaries of a given structure of interest. Such execution can yield a coarse or approximate edge localization, which can be considered as indicating where in the given image the deep learning neural network believes that the perimetral boundary of the given structure of interest is located. Note that the term “coarse or approximate” can be appropriate, due to the above-mentioned tendency of deep learning edge localization to overshoot or undershoot. Various embodiments described herein can further include automatically inserting image processing calipers into the given image, based on the coarse or approximate edge localization. In particular, multiple image processing calipers can be inserted into the given image at respective locations around or along the coarse or approximate edge localization. In various aspects, each image processing caliper can cover a respective straight line of pixels that is bisected by and orthogonal to the coarse or approximate edge localization. In some instances, the multiple image processing calipers can be evenly spaced or distributed around the coarse or approximate edge localization. In any case, activation or execution of the multiple image processing calipers can yield a fine edge localization that is more accurate than (e.g., that has less overshoot or undershoot than) the coarse or approximate edge localization, hence the term “fine. ” In other words, various embodiments described can be considered as leveraging the deep learning neural network so as to identify where the image processing calipers should be placed or inserted. In this way, the heightened localization accuracy of imaging processing calipers can be achieved in conjunction with the convenience or low-time-consumption of deep learning. That is, various embodiments described herein can be considered as achieving the “best of both worlds”in comparison to existing techniques.

Various embodiments described herein can be considered as a computerized tool (e.g., any suitable combination of computer-executable hardware or computer-executable software) that can facilitate edge localization via intelligent insertion of image processing calipers. In various aspects, such computerized tool can comprise an access component, a scan component, a coarse component, or a fine component.

In various embodiments, there can be a charged-particle microscope. In various aspects, the charged-particle microscope can exhibit any suitable design or construction (e.g., can be an SEM, can be a TEM, can be a dual-beam microscope). In various instances, there can be any suitable specimen (e.g., semiconductor wafer or lamella) that is loaded in the charged-particle microscope (e.g., that is currently located or positioned on an actuatable stage of the charged-particle microscope). In various cases, the specimen can have or otherwise contain a structure of interest (e.g., fin, gate, drain, nanowire, organelle, contaminant particle).

In various cases, it can be desired to localize within the specimen an edge, boundary, or perimeter of the structure of interest. As described herein, the computerized tool can facilitate such localization.

In various embodiments, the access component of the computerized tool can electronically access the charged-particle microscope. For instance, the access component can send electronic commands to, or can receive electronic data from, the charged-particle microscope. In some cases, the access component can be considered as a conduit through which other components of the computerized tool can electronically interact with (e.g., activate, deactivate, read, write, edit, copy, manipulate) the charged-particle microscope.

In various embodiments, the scan component of the computerized tool can electronically cause the charged-particle microscope to scan the specimen, thereby yielding a scanned image (e.g., a two-dimensional or three-dimensional SEM scanned image, a two-dimensional or three-dimensional TEM scanned image) that depicts or illustrates at least some portion of the specimen. In other words, the scan component can electronically instruct or command the charged-particle microscope to generate the scanned image. In various instances, the scan component can cause the charged-particle microscope to perform such scanning according to any suitable default microscopy protocol that is known or deemed to be non-destructive or non-damaging for wide swaths or proportions of possible microscopy specimens. As a non-limiting example, the default microscopy protocol can involve using a default beam current (e.g., on the order of nano-amps (nA) or pico-amps (pA)) and a default beam voltage (e.g., less than 5 kilo-volts (kV)) that are sufficiently low so as to be known or expected to not damage, deteriorate, or otherwise degrade all, most, or any suitable subgroup of whatever possible specimens that the charged-particle microscope is expected or designed to encounter. In other cases, the scan component can cause the charged-particle microscope to perform such scanning according to any suitable microscopy protocol that is selected by a user or technician (e.g., such microscopy protocol can be typed or spoken by the user or technician into any suitable GUI text field or microphone of the charged-particle microscope).

In various embodiments, the coarse component of the computerized tool can electronically store, maintain, control, or otherwise access a deep learning neural network. In various aspects, the deep learning neural network can exhibit any suitable internal architecture. For example, the deep learning neural network can include any suitable numbers of any suitable types of layers (e.g., input layer, one or more hidden layers, output layer, any of which can be convolutional layers, dense layers, long short-term memory (LSTM) layers, non-linearity layers, pooling layers, batch normalization layers, or padding layers). As another example, the deep learning neural network can include any suitable numbers of neurons in various layers (e.g., different layers can have the same or different numbers of neurons as each other). As yet another example, the deep learning neural network can include any suitable activation functions (e.g., softmax, sigmoid, hyperbolic tangent, rectified linear unit) in various neurons (e.g., different neurons can have the same or different activation functions as each other). As still another example, the deep learning neural network can include any suitable interneuron connections or interlayer connections (e.g., forward connections, skip connections, recurrent connections).

Regardless of its specific internal architecture, the deep learning neural network can be configured or trained to localize boundaries of the structure of interest in inputted images. Accordingly, the coarse component can electronically execute the deep learning neural network on the scanned image, and such execution can yield a coarse boundary localization. For example, the coarse component can feed the scanned image to an input layer of the deep learning neural network, the scanned image can complete a forward pass through one or more hidden layers of the deep learning neural network, and an output layer of the deep learning neural network can calculate the coarse boundary localization based on activations provided by the one or more hidden layers of the deep learning neural network.

In any case, the coarse boundary localization can be any suitable electronic data that indicates (e.g., via a segmentation mask) where, within the image, a perimetral edge or boundary of the structure of interest is located (as inferred or predicted by the deep learning neural network). That is, the deep learning neural network can be considered as evaluating the pixels or voxels of the image, so as to distinguish between pixels or voxels that collectively make up or belong to the perimetral edge or boundary of the structure of interest and pixels or voxels that instead collectively make up or belong to anything else (e.g., any other background object), and the coarse boundary localization can represent, indicate, or otherwise specify the locations of the former pixels or voxels. Because the deep learning neural network can be vulnerable to at least some non-zero amount of edge overshooting or edge undershooting, the coarse boundary localization might not be fully coextensive with the true (but as yet unknown) perimetral edge or boundary of the structure of interest. So, the term “coarse”is used to convey this possibility for localization inaccuracy.

In various embodiments, the fine component of the computerized tool can electronically generate a fine boundary localization, based on the coarse boundary localization and based on a plurality image processing calipers. Specifically, the plurality of image processing calipers can include any suitable number of image processing calipers, each being able to detect or localize an edge along a respective line of pixels (or voxels) by examining a spatial derivative of whatever intensity profile corresponds to that respective line of pixels (e.g., by determining where along that respective line of pixels the absolute value of the derivative of the intensity profile exceeds some threshold magnitude). In various aspects, the fine component can electronically insert the plurality of image processing calipers into the scanned image, based on the coarse boundary localization. In particular, the fine component can insert each of the plurality of image processing calipers into the scanned image at a respective, distinct, or otherwise unique location that is on or along the coarse boundary localization, such that each image processing caliper can be considered as intersecting (e.g., can be considered as analyzing a line of pixels which intersects) the coarse boundary localization. In some instances, the fine component can cause each image processing caliper to be inserted into the scanned image so as to be orthogonally or perpendicularly oriented with respect to the coarse boundary localization. In various cases, the fine component can cause each image processing caliper to be inserted into the scanned image so that its respective line of pixels is centered about or bisected by the coarse boundary localization. In some aspects, the fine component can cause the plurality of image processing calipers to be inserted into the scanned image such that they are evenly spaced or evenly distributed around the coarse boundary localization. In various instances, the fine component can cause the plurality of image processing calipers to be inserted into the scanned image such that every two adjacent image processing calipers are not spatially separated from each other by any intervening or intermediary pixels. However, in various other instances, the fine component can cause the plurality of image processing calipers to be inserted into the scanned image such that every two adjacent image processing calipers are spatially separated from each other by one or more intervening or intermediary pixels.

In any case, the fine component can execute or otherwise activate the plurality of image processing calipers, and such execution or activation can yield the fine boundary localization. In various aspects, the fine boundary localization can be any suitable electronic data that indicates (e.g., via a segmentation mask) where, within the image, a perimetral edge or boundary of the structure of interest is located. In various instances, because the plurality of image processing calipers can be inserted into the scanned image around or along the coarse boundary localization, and because image processing calipers can be significantly less vulnerable to edge overshooting or edge undershooting than deep learning neural networks, the fine boundary localization can be considered as being more coextensive with the true (but as yet unknown) perimetral edge or boundary of the structure of interest than the coarse boundary localization. So, the term “fine” is used to convey this increase in localization accuracy. More specifically, each image processing caliper can be located or centered on a respective pixel that is part of the coarse boundary localization. In other words, each image processing caliper can be located or centered on a respective pixel which the deep learning neural network inferred belongs to the perimetral edge of the structure of interest. In various cases, each image processing caliper can be considered as checking or refining the deep learning neural network's inference at its respective pixel. That is, each image processing caliper can be considered as determining, via spatial derivative analysis of a straight line of pixels which is centered about that respective pixel and which is oriented orthogonally to the coarse boundary localization at that respective pixel, whether the deep learning neural network overshot or undershot its inference at that respective pixel. If any image processing caliper fails to detect such overshooting or undershooting at its respective pixel, then the fine component can include in the fine boundary localization that respective pixel. Conversely, if any image processing caliper detects such overshooting or undershooting at its respective pixel, then the fine component can refrain from including in the fine boundary localization that respective pixel and can instead include in the fine boundary localization whichever new pixel is indicated or identified by the image processing caliper. Accordingly, each of the plurality of image processing calipers can be considered as refining a respective portion or segment of the coarse boundary localization, and the collective result of such refinement can be considered as the fine boundary localization.

Note that even-spacing or even-distribution of the plurality of image processing calipers around or along the coarse boundary localization can help to increase the accuracy or reliability of the fine boundary localization (e.g., can help to ensure that refinement is evenly or proportionally performed around the entire circumference or perimeter of the coarse boundary localization). Additionally, note that having no or few intervening pixels between each pair of adjacent image processing calipers can yet further enhance the accuracy of the fine boundary localization (e.g., even spacing/distribution and no or few intervening pixels can mean that a larger total number of image processing calipers are inserted along or around the coarse boundary localization, thereby effectively increasing the resolution of refinement that is applied to the coarse boundary resolution). Conversely, note that having a greater number of intervening pixels between each pair of adjacent image processing calipers can reduce the computational footprint involved in generating the fine boundary localization (e.g., even spacing/distribution and more intervening pixels can mean that a smaller total number of image processing calipers are inserted along or around the coarse boundary localization, thereby reducing the amount of refinement computations needed to generate the fine boundary localization).

In any case, various embodiments described herein can achieve both accuracy and convenience for edge localization. Indeed, the deep learning neural network can be considered as quickly, efficiently, or otherwise in non-time-consuming fashion identifying an estimated or approximated location of the perimetral edge of the structure of interest, and the image processing calipers which can be automatically inserted around or along that estimation or approximation can produce a more accurate localization of the perimetral edge of the structure of interest. That is, the deep learning neural network can quickly produce a “ballpark estimate”, and the image processing calipers can increase the accuracy of that “ballpark estimate”. Thus, various embodiments described herein can achieve higher edge localization accuracy than existing techniques which rely upon deep learning, and various embodiments described herein can also achieve less time-consumption than existing techniques that rely upon manual placement of image processing calipers.

In various embodiments, the fine component can electronically transmit the fine boundary localization to any suitable computing device. In other embodiments, the fine component can electronically render the fine boundary localization on any suitable electronic display. Accordingly, a user or technician of the charged-particle microscope can become aware of the fine boundary localization.

Note that, in order for the boundary localizations described herein to be accurately generated, the deep learning neural network can first undergo training. In various cases, the computerized tool can train the deep learning neural network using any suitable training paradigms (e.g., via supervised training, unsupervised training, or reinforcement learning), as described later herein.

Various embodiments described herein can be employed to use hardware or software to solve problems that are highly technical in nature (e.g., to facilitate edge localization via intelligent insertion of image processing calipers), that are not abstract and that cannot be performed as a set of mental acts by a human. Further, some of the processes performed can be performed by a specialized computer (e.g., electron microscopes such as SEMs, TEMs, or dual-beam microscopes; machine learning models such as deep learning neural networks) for carrying out defined acts related to the field of charged-particle microscopy.

For example, such defined acts can include: accessing, by a device operatively coupled to a processor, an image captured by a charged-particle microscope, wherein the image depicts a specimen; localizing, by the device and via execution of a deep learning neural network on the image, an approximate boundary of a structure of interest of the specimen; and localizing, by the device, a true boundary of the structure of interest, based on placing a plurality of image processing calipers along the approximate boundary. In some cases, each of the plurality of image processing calipers can detect a respective portion of the true boundary based on comparing: a spatial derivative of a respective pixel intensity profile that intersects with the approximate boundary; to a threshold derivative magnitude. In various aspects, a first image processing caliper of the plurality of image processing calipers can correspond to (e.g., can analyze or evaluate) a first pixel intensity profile, and a first location along the first pixel intensity profile can correspond to (e.g., can belong to) the approximate boundary. In various instances, the first location can bisect or be centered on the first pixel intensity profile. In various cases, the first pixel intensity profile can be oriented perpendicularly to the approximate boundary at the first location. In various aspects, the plurality of image processing calipers can be evenly spaced along the approximate boundary. In various aspects, any pair of adjacent image processing calipers can be separated by no intervening pixels or instead by one or more intervening pixels.

Such defined acts are inherently computerized. Indeed, a charged-particle microscope (e.g., SEM, TEM, dual beam microscope) is a highly-technical computerized device comprising specific computerized hardware (e.g., temperature sensors, pressure sensors, voltage sensors, ion beam emitters, electron beam emitters, focusing lenses, ion detectors, electron detectors, beam apertures, fluid valves, actuatable specimen stages). A charged-particle microscope and the images that it captures cannot be implemented by the human mind, or by a human with pen and paper, in any reasonable or practicable way without computers. Furthermore, artificial neural networks (e.g., deep learning edge localizers) are also inherently computerized constructs comprising specific software-oriented architectures (e.g., input layers, hidden layers, or output layers, any of which can be made up of trainable or non-trainable internal parameters such as convolutional layers or LSTM layers). Artificial neural networks cannot be trained or executed by the human mind, or by humans with mere pen and paper, in any reasonable or practicable way without computers. Further still, edge localization is an inherently computer-centric task that focuses on enabling computers to automatically locate the perimetral boundaries of visible structures of interest within charged-particle microscopy images. It would make no sense whatsoever to discuss charged-particle microscopy edge localization outside of a computerized context.

Moreover, various embodiments described herein can integrate into a practical application various teachings relating to the field of charged-particle microscopy. As explained above, some existing techniques for facilitating edge localization for charged-particle microscopy images involve manual placement of image processing calipers. Although such existing techniques can achieve high localization accuracy (e.g., image processing calipers are not prone to undershooting or overshooting edges), they are excessively time-consuming (e.g., it can take a user or operator several minutes to localize the perimetral boundary of a single structure of interest using manually-placed image processing calipers). Thus, such existing techniques can be considered as problematic or disadvantageous, since real-world operational contexts often require that edge localization be performed for hundreds, thousands, or even millions of charged-particle microscopy images in short timeframes. As also explained above, other existing techniques for facilitating edge localization for charged-particle microscopy images involve training a deep learning neural network to visually recognize which pixels belong to the perimetral boundary of a structure of interest and which pixels do not. Although such other existing techniques can be considered as quick or efficient (e.g., the execution time of a trained deep learning edge localizer can be on the order of mere seconds or fractions of a second), such other existing techniques can be prone to at least some amount of edge overshooting or edge undershooting (e.g., due to the statistical, aggregatory nature of deep learning training, the deep learning neural network can become likely to erroneously infer that certain structures of interest are larger than they actually are and that other structures of interest are smaller than they actually are). Thus, such other existing techniques can be considered as problematic or disadvantageous, since real-world operational contexts that rely upon charged-particle microscopy images often demand micrometer-level precision or even nanometer-level precision in edge localization. So, existing techniques can be considered as suffering from various technical problems.

Various embodiments described herein can help to ameliorate one or more of these technical problems, by implementing edge localization via intelligent insertion of image processing calipers. In particular, when given an image of a specimen, various embodiments described herein can involve executing on that given image a deep learning edge localizer, thereby yielding a first boundary localization (e.g., a first segmentation mask) showing which pixels of the given image belong (in the opinion of the deep learning edge localizer) to the perimetral edge of a structure of interest of the specimen and which pixels do not belong to that perimetral edge.

Because the deep learning edge localizer can be prone to at least some non-zero amount of edge overshoot or undershoot, this first boundary localization can be considered as being a coarse approximation of the perimetral edge of the structure of interest. In various aspects, various embodiments described herein can involve inserting into the given image multiple image processing calipers, such that those calipers perpendicularly intersect with and are arranged spatially around the first boundary localization. In various instances, various embodiments described herein can involve executing or otherwise activating those multiple image processing calipers, thereby yielding a second boundary localization. Because image processing calipers can be not prone to edge overshooting or undershooting, this second boundary localization can be considered as being a finer or more accurate approximation of the perimetral edge of the structure of interest. In other words, the deep learning edge localizer can be considered as generating a “close-enough” approximation of where the perimetral edge of the structure of interest is located in the given image, and any gaps or errors in between that “close-enough” approximation and the true perimetral edge can be detected or otherwise accounted for by the image processing calipers. In this way, the high edge localization accuracy of image processing calipers can be achieved with the speed or convenience of deep learning. Contrast this with the above-mentioned existing techniques, which either sacrifice speed/convenience for accuracy or sacrifice accuracy for speed/convenience.

Additionally, the counter-intuitive character of various embodiments described herein must be emphasized. Indeed, as explained above, a first group of existing techniques rely upon manual placement of image processing calipers, and a second group of existing techniques instead rely upon deep learning. Prior to the teachings described herein and to the inventive work performed by the present inventors, those first and second groups of existing techniques were considered to be separate alternatives for each other. In other words, those first and second groups of existing techniques were considered to be mutually exclusive. Indeed, if a given user or technician valued accuracy over convenience, that given user or technician would utilize manually-placed image processing calipers rather than deep learning. Conversely, if a given user or technician instead valued convenience over accuracy, that given user or technician would instead utilize deep learning rather than manually-placed image processing calipers. The present inventors were the first to devise the herein described techniques which counter-intuitively combine the convenience of deep learning with the accuracy of image processing calipers. The way this is achieved is by using the edge localizations produced by deep learning to determine where image processing calipers should be inserted. In other words, the image processing calipers can be intelligently inserted at intra-image locations that are determined by deep learning (e.g., can be centered on or bisected by, and perpendicular to, intra-image locations which the deep learning model thinks belong to the perimetral edge of the structure of interest).

Because manually-placed image processing calipers and deep learning were previously considered to be mutually-exclusive techniques of facilitating edge localization, it would certainly not be expected, obvious, or intuitive to insert image processing calipers at locations determined by deep learning as taught by various embodiments described herein.

For at least the above reasons, various embodiments described herein can be considered as addressing or ameliorating various problems or disadvantages that afflict existing techniques for facilitating edge localization with respect to charged-particle microscopy. Therefore, various embodiments described herein can be considered as a concrete and tangible technical improvement in the field of charged-particle microscopy. Accordingly, various embodiments described herein certainly qualify as useful and practical applications of computers.

Furthermore, various embodiments described herein can control real-world tangible devices based on the disclosed teachings. For example, various embodiments described herein can electronically activate, deactivate, or otherwise actuate real-world hardware (e.g., ion beam emitters, ion focusing lenses, carrier fluid valves/pumps) of real-world charged-particle microscopes (e.g., SEMs, TEMs, dual-beam microscopes).

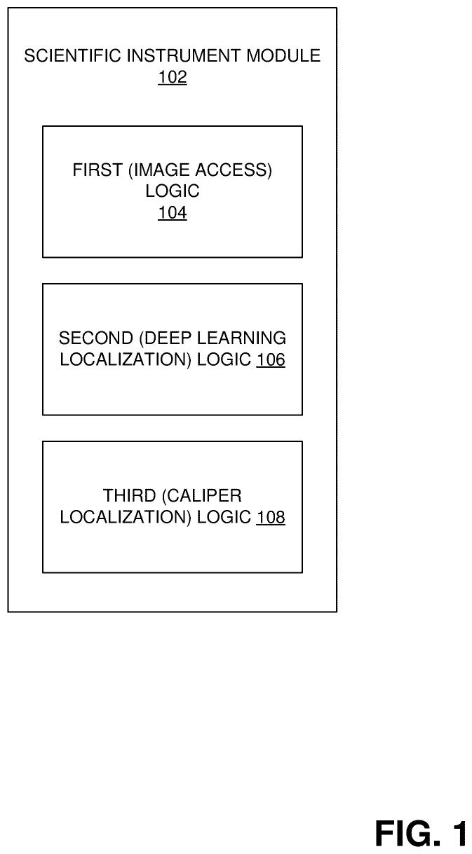

FIG. 1 illustrates an example, non-limiting block diagram of a scientific instrument module 102 in accordance with various embodiments described herein.

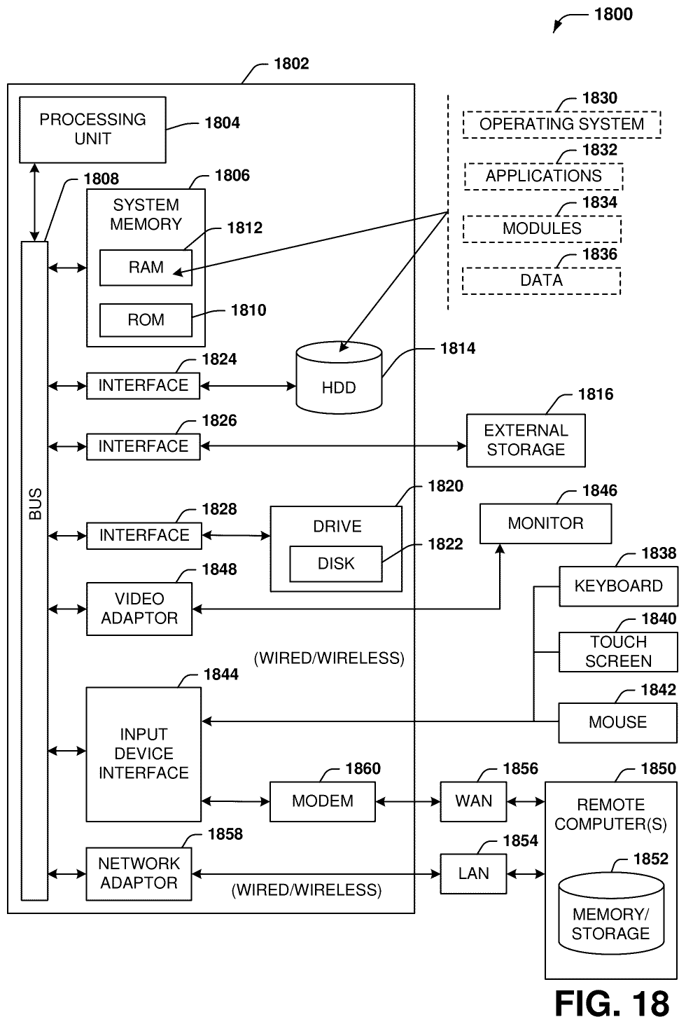

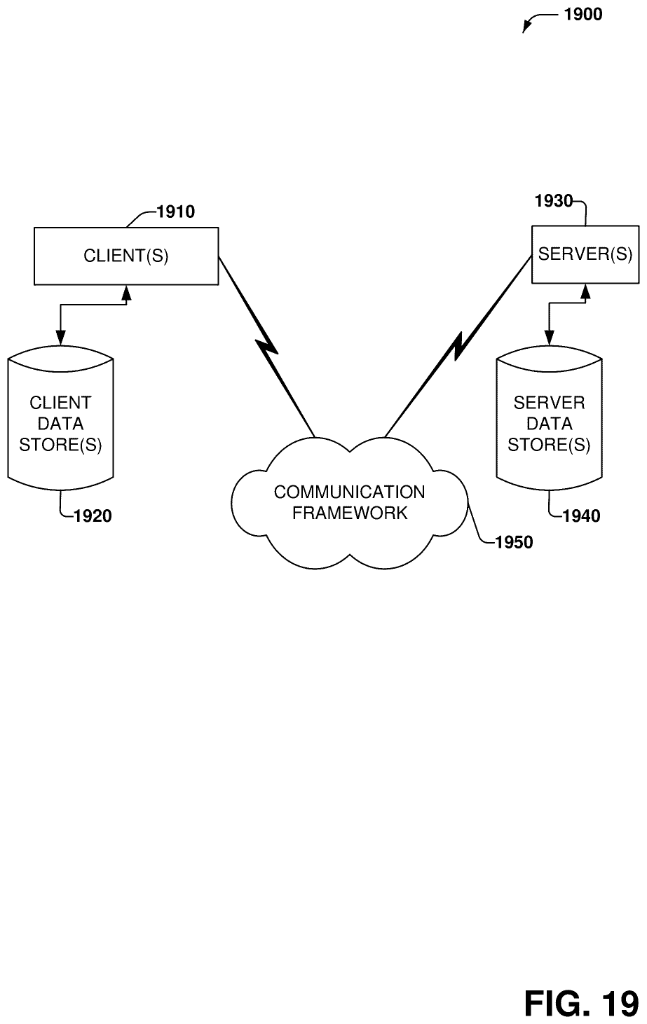

In various embodiments, the scientific instrument module 102 can be implemented by circuitry (e.g., including electrical or optical components), such as a programmed computing device. Logic of the scientific instrument module 102 can be included in a single computing device or can be distributed across multiple computing devices that are in communication with each other as appropriate. Examples of computing devices that may, singly or in combination, implement the scientific instrument module 102 are discussed herein with reference to FIG. 18, and examples of systems or networks of interconnected computing devices, in which the scientific instrument module 102 may be implemented across one or more of the computing devices, are discussed herein with reference to FIG. 19.

The scientific instrument module 102 can include first logic 104, second logic 106, and third logic 108. As used herein, the term “logic” can include an apparatus that is to perform a set of operations associated with the logic. For example, any of the logic elements included in the scientific instrument module 102 can be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” can refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices. A module can omit one or more of the logic elements depicted in the associated drawings; for example, a module may include a subset of the logic elements depicted in the associated drawings when that module is to perform a subset of the operations discussed herein with reference to that module.

In various embodiments, there can be a scientific instrument corresponding to the scientific instrument module 102. In various aspects, the scientific instrument can be any suitable computerized device that can electronically measure some scientifically-relevant, clinically-relevant, or research-relevant characteristic, property, or attribute of an analytical specimen (e.g., of a known or unknown mixture, compound, or collection of matter). As a non-limiting example, a scientific instrument can be a scanning electron microscope. In such case, the scientific instrument can capture images of the analytical specimen, so as to measure or determine a surface topography, a surface material composition, or a crystallographic structure of the analytical specimen. As another non-limiting example, a scientific instrument can be a transmission electron microscope. In such case, the scientific instrument can capture images of the interior of the analytical specimen, so as to measure or determine interior structural details of the analytical specimen. As even another non-limiting example, a scientific instrument can be a dual beam microscope. In such case, the scientific instrument can capture images of the analytical specimen in addition to being able to mill the analytical specimen. As a more general non-limiting example, a scientific instrument can be any suitable type of charged-particle microscope (e.g., some types of microscopes can use beams of non-electron ions to capture images).

In various embodiments, the first logic 104 can access an image captured or generated by the scientific instrument. In various aspects, the image can depict any suitable analytical specimen.

In various embodiments, the second logic 106 can involve localizing, via execution of a deep learning neural network on the image, an approximate boundary of a structure of interest of the analytical specimen. More specifically, the deep learning neural network can be an edge localizer that is configured to receive as input an image and to produce as output a segmentation mask that shows which individual pixels (or voxels) of the inputted image are inferred to belong to a boundary or perimeter of some structure of interest that is depicted in the inputted image. Because the deep learning neural network can be likely to exhibit some non-zero amount of edge overshooting or edge undershooting, the pixels that are indicated by the outputted segmentation mask might not truly be the pixels which actually make up the boundary or perimeter of the structure of interest. Accordingly, such segmentation mask can be referred to as “approximate”.

In various embodiments, the third logic 108 can involve localizing a true boundary of the structure of interest, based on placing a plurality of image processing calipers along the approximate boundary. In various aspects, each image processing caliper can be an electronic tool or functionality that can detect or localize a depicted edge by analyzing the spatial derivative of intensity values of some respective line of pixels or voxels (e.g., can determine where along that line of pixels an edge, if any, is located). In various instances, each of the plurality of image processing calipers can be inserted into the image, such that its respective line of pixels orthogonally intersects the approximate boundary at some respective location or position around, about, or along the approximate boundary. In various cases, the plurality of image processing calipers can all analyze lines of pixels that are of equal length to each other and that are bisected by the approximate boundary (e.g., such that half of each image processing caliper extends outward from the approximate boundary, and such that a remaining half of each image processing caliper extends inward from the approximate boundary). In some aspects, the plurality of image processing calipers can be evenly spaced around or along the approximate boundary. In some instances, each pair of adjacent image processing calipers can be separated from each other by one or more intervening pixels or voxels of the image. In other instances, each pair of adjacent image processing calipers can be separated from each other by no intervening pixels or voxels of the image. In any case, whatever pixels make up the approximate boundary can be considered as intelligent or promising sites for the insertion of the plurality of image processing calipers. In other words, although the approximate boundary might itself not be completely coextensive with the true boundary of the structure of interest, the approximate boundary can be considered as being close-enough to that true boundary such that the true boundary can then be accurately localized by the plurality of image processing calipers. For example, each image processing caliper can be considered as refining or validating a respective portion of the approximate boundary by determining whether the approximate boundary at its respective location should be extended outward in the image, extended inward in the image, or preserved where it is in the image. In this way, the scientific instrument module 102 can be able to facilitate edge or boundary localization in both an accurate (due to the image processing calipers) and time-efficient (due to the deep learning neural network) fashion, unlike existing techniques which sacrifice accuracy for time-efficiency or vice versa.

Accordingly, the scientific instrument module 102 can facilitate edge localization via intelligent insertion of image processing calipers.

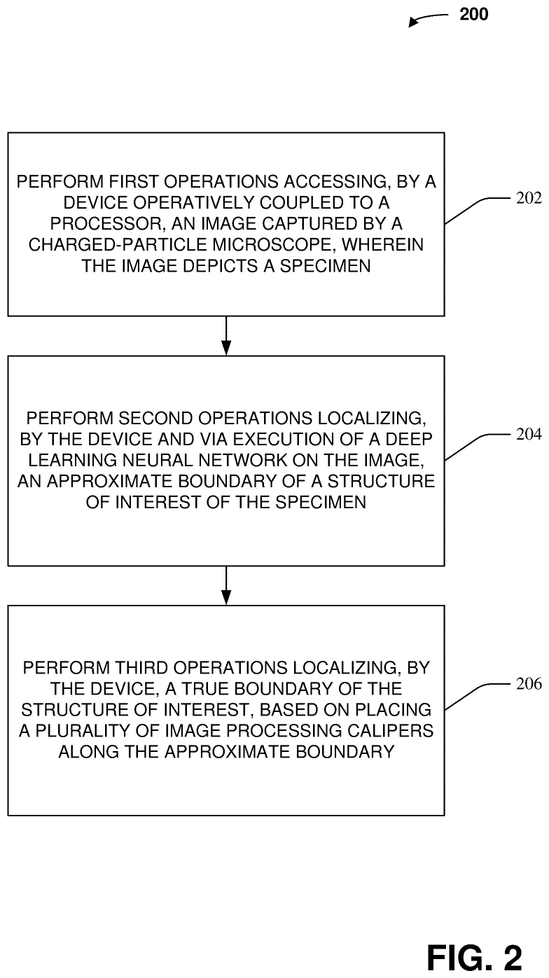

FIG. 2 is an example, non-limiting flow diagram of a computer-implemented method 200 in accordance with various embodiments described herein. The operations of the computer-implemented method 200 may be used in any suitable context to perform any suitable operations (e.g., can be performed by or used in conjunction with any of the various modules, computing devices, or graphical user interfaces described with respect to FIGS. 18-19. Operations are illustrated once each and in a particular order in FIG. 2, but the operations may be reordered or repeated as desired and appropriate (e.g., different operations performed may be performed in parallel, as suitable).

In various aspects, act 202 can include performing first operations accessing, by a device operatively coupled to a processor, an image captured by a charged-particle microscope, wherein the image can depict an analytical specimen. In various cases, the first logic 104 can perform or otherwise facilitate act 202.

In various aspects, act 204 can include performing second operations localizing, by the device and via execution of a deep learning neural network on the image, an approximate boundary of a structure of interest of the specimen. In various cases, the second logic 106 can perform or otherwise facilitate act 204.

In various instances, act 206 can include performing third operations localizing, by the device, a true boundary of the structure of interest, based on placing a plurality of image processing calipers along the approximate boundary. In various cases, the third logic 108 can perform or otherwise facilitate act 206.

Accordingly, the computer-implemented method 200 can facilitate edge localization via intelligent insertion of image processing calipers.

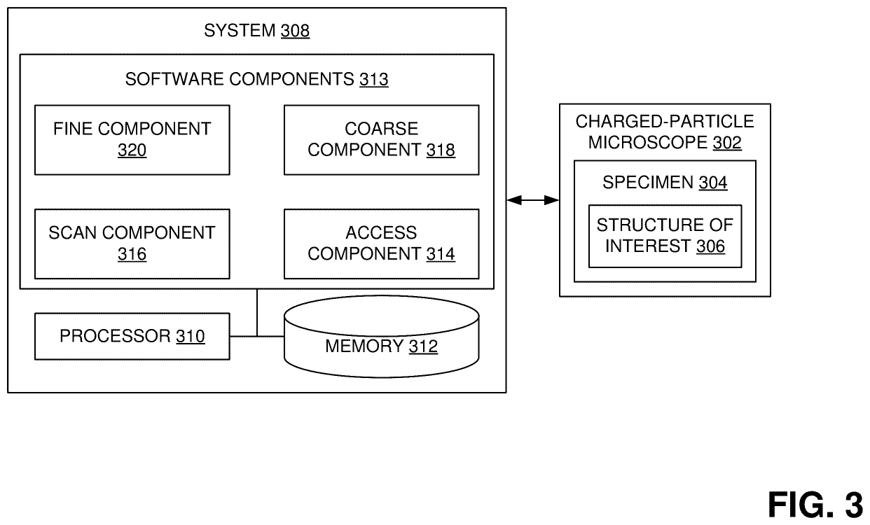

FIG. 3 illustrates a block diagram of an example, non-limiting system that can facilitate edge localization via intelligent insertion of image processing calipers in accordance with one or more embodiments described herein.

In various embodiments, there can be a charged-particle microscope 302. In various aspects, the charged-particle microscope 302 can be as described above. That is, the charged-particle microscope 302 can be any suitable computerized device that can leverage its constituent hardware (e.g., electron sources, anodes, condenser lenses, condenser apertures, scan coils, objective lenses, objective apertures, deflectors, condensers, stigmators, electron detectors, X-ray detectors, actuatable specimen stages) to electronically capture any suitable image of any suitable analytical specimen. As a non-limiting example, the charged-particle microscope 302 can be any suitable SEM. As another non-limiting example, the charged-particle microscope 302 can be any suitable TEM. As yet another non-limiting example, the charged-particle microscope 302 can be any suitable dual-beam microscope.

Although not explicitly shown in the figures, the charged-particle microscope 302 can be electronically integrated with any suitable human-computer interface device, which can be remote from or local to the charged-particle microscope 302. Accordingly, a user or technician associated with the charged-particle microscope 302 can interact with or otherwise control the charged-particle microscope 302. Some non-limiting examples of the human-computer interface device can be a keyboard of the charged-particle microscope 302, a keypad of the charged-particle microscope 302, a touchscreen of the charged-particle microscope 302, or a voice-command system of the charged-particle microscope 302.

Although not explicitly shown in the figures, the charged-particle microscope 302 can comprise a plurality of configurable operating settings. In various aspects, each of the plurality of configurable operating settings can be any suitable hardware-related characteristic or software-related characteristic of the charged-particle microscope 302 that can guide, affect, or otherwise dictate how the charged-particle microscope 302 runs, operates, or functions with respect to any given analytical specimen and that can be selectively controlled, changed, adjusted, or otherwise set by the user or technician (e.g., via interaction with the human-computer interface device of the charged-particle microscope 302). As a non-limiting example, any of the plurality of configurable operating settings can be a user-controllable electric voltage setting (e.g., beam voltage) or electric current setting (e.g., beam current), which can allow the user or technician to selectively control an electrode of the charged-particle microscope 302, so as to selectively increase or decrease an electric voltage or electric current within, or that is applied by, the charged-particle microscope 302. As another non-limiting example, any of the plurality of configurable operating settings can be a user-controllable temperature setting, which can allow the user or technician to control a heater (e.g., stage heater, heating coil) or cooler (e.g., cooling fan, heat pump, refrigerator) of the charged-particle microscope 302, so as to selectively increase or decrease a temperature within, or that is applied by, the charged-particle microscope 302. As still another non-limiting example, any of the plurality of configurable operating settings can be a user-controllable mechanical actuator setting, which can allow the user or technician to control a mechanical actuator (e.g., electric motor, specimen stage, iris aperture, fluid pump or syringe) of the charged-particle microscope 302, so as to selectively move the mechanical actuator. As yet another non-limiting example, any of the plurality of configurable operating settings can be a user-controllable optics setting, which can allow the user or technician to control an optical element (e.g., optical lens, optical deflector) of the charged-particle microscope 302, so as to selectively change an optical quality (e.g., focal spot size or location, astigmatism, defocus) that is applied by the charged-particle microscope 302.

In various instances, the charged-particle microscope 302 can be loaded with a specimen 304. As a non-limiting example, the specimen 304 can be presently positioned, located, or otherwise affixed onto the specimen stage of the charged-particle microscope 302, such that the specimen 304 is analyzable or scannable by the charged-particle microscope 302. In various cases, the specimen 304 can be any suitable type of synthetic sample or naturally-occurring sample that can exhibit any suitable physical, chemical, compositional, or other properties, attributes, or characteristics. In the case of synthetic specimens, the specimen 304 can be manufactured by any suitable microfabrication or nanofabrication techniques, such as etching, milling, or deposition. As a non-limiting example, the specimen 304 can be a lamella taken from a semiconductor substrate or wafer. As another non-limiting example, the specimen 304 can be any other suitable integrated circuit element or printed circuit board element. However, in the case of naturally-occurring specimens, the specimen 304 can be an organic or biological sample (e.g., a tissue sample).

In various aspects, the specimen 304 can comprise a structure of interest 306. In various aspects, the structure of interest 306 can be any suitable physical thing that is a discrete, constituent part or portion of the specimen. As a non-limiting example, the structure of interest 306 can be a transistor gate that is fabricated in or on the specimen 304. As another non-limiting example, the structure of interest 306 can be a transistor fin that is fabricated in or on the specimen 304. As still another non-limiting example, the structure of interest 306 can be a transistor drain that is fabricated in or on the specimen 304. As yet another non-limiting example, the structure of interest 306 can be a nanowire that is fabricated in or on the specimen 304. As even another non-limiting example, the structure of interest 306 can be a cellular nucleus or other organelle that has grown within or on the specimen 304.

In various instances, it can be desired to localize an edge, boundary, or perimeter of the structure of interest 306. In other words, it can be desired to determine where in or on the specimen 304 the edge, boundary, or perimeter of the structure of interest 306 is located or positioned. In various cases, a system 308, which can be electronically integrated (e.g., via any suitable wired or wireless electronic connections) with the charged-particle microscope 302, can accomplish such localization as described herein.

In various aspects, the system 308 can comprise a processor 310 (e.g., computer processing unit, microprocessor) and a non-transitory computer-readable memory 312 that is operably or operatively or communicatively connected or coupled to the processor 310. The non-transitory computer-readable memory 312 can store computer-executable instructions which, upon execution by the processor 310, can cause the processor 310 or other components of the system 308 (e.g., access component 314, scan component 316, coarse component 318, fine component 320) to perform one or more acts. In various embodiments, the non-transitory computer-readable memory 312 can store computer-executable components (e.g., access component 314, scan component 316, coarse component 318, fine component 320), and the processor 310 can execute the computer-executable components.

In various embodiments, the system 308 can comprise an access component 314. In various aspects, the access component 314 can electronically access the charged-particle microscope 302. That is, the access component 314 can electronically communicate or otherwise electronically interact with (e.g., transmit electronic instructions or commands to, receive electronic data from) the charged-particle microscope 302. Accordingly, the access component 314 can be considered as a proxy or conduit through which other components of the system 308 can interact with, communicate with, or otherwise manipulate the charged-particle microscope 302. However, these are mere non-limiting examples. In other cases, the access component 314 can be omitted, and any other components of the system 308 can communicate or interact directly with the charged-particle microscope 302.

In various embodiments, the system 308 can comprise a scan component 316. In various aspects, the scan component 316 can, as described herein, cause the charged-particle microscope 302 to capture an image of the specimen 304.

In various embodiments, the system 308 can comprise a coarse component 318. In various instances, the coarse component 318 can, as described herein, leverage a deep learning neural network to coarsely or approximately localize the edge, boundary, or perimeter of the structure of interest 306.

In various embodiments, the system 308 can comprise a fine component 320. In various instances, the fine component 320 can, as described herein, finely or accurately localize the edge, boundary, or perimeter of the structure of interest 306, by placing or inserting image processing calipers along or around whatever localization was produced by the deep learning neural network of the coarse component 318.

Note that, in various instances, the access component 314, the scan component 316, the coarse component 318, and the fine component 320 can collectively be considered as being one or more software components 313 of the system 308. In various aspects, it should be appreciated that the one or more software components 313 are described primarily herein as comprising four components (e.g., the access component 314, the scan component 316, the coarse component 318, and the fine component 320) for ease of explanation and illustration. However, the one or more software components 313 are not limited to being implemented as exactly such four components in every embodiment. Indeed, in some embodiments, the functionalities described herein of such four components can be combined in any suitable fashions, so as to be implemented in or by fewer than four components (e.g., in some cases, a single component can perform all of the functionalities that are described herein with respect to the access component 314, the scan component 316, the coarse component 318, and the fine component 320). In other embodiments, the functionalities described herein of such four components can instead be distributed, separated, split, or fragmented in any suitable fashions, so as to be implemented in or by more than four components (e.g., two or more components can facilitate the functionalities that are performable by the access component 314; two or more components can facilitate the functionalities that are performable by the scan component 316; two or more components can facilitate the functionalities that are performable by the coarse component 318; two or more components can facilitate the functionalities that are performable by the fine component 320).

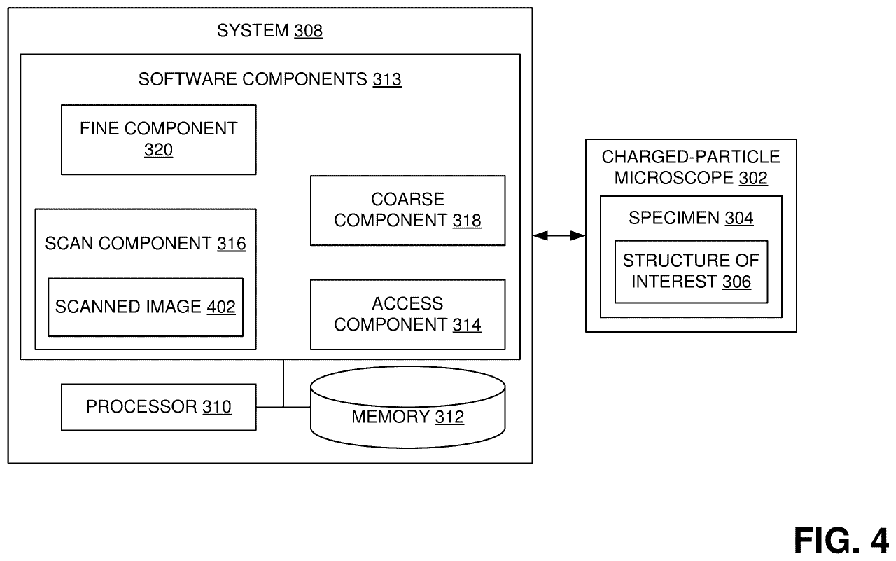

FIG. 4 illustrates a block diagram of an example, non-limiting system including a scanned image that can facilitate edge localization via intelligent insertion of image processing calipers in accordance with one or more embodiments described herein.

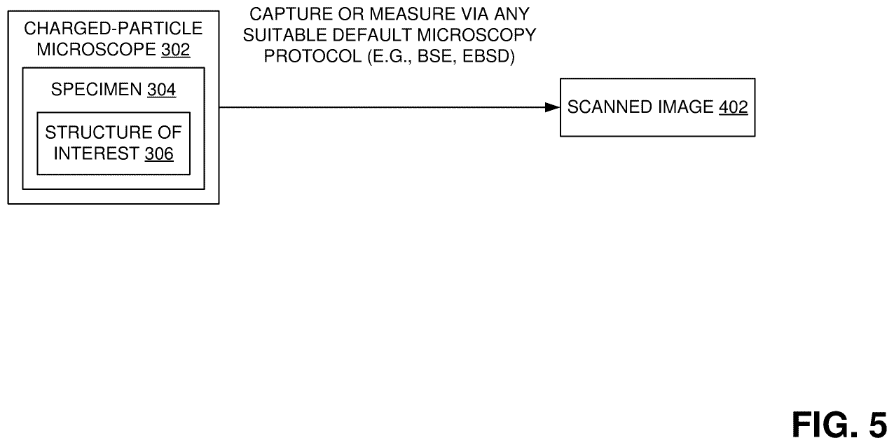

In various embodiments, the scan component 316 can electronically cause the charged-particle microscope 302 to capture or otherwise generate a scanned image 402 of the specimen 304. Various non-limiting aspects are described with respect to FIG. 5.

FIG. 5 illustrates an example, non-limiting block diagram showing how the scanned image 402 can be obtained in accordance with one or more embodiments described herein.

In various embodiments, the scan component 316 can, in response to receipt or accessing of any suitable user-provided trigger or signal, electronically instruct or electronically command the charged-particle microscope 302 to scan the specimen 304.

In various aspects, such scanning can be in accordance with any suitable default microscopy protocol that is implementable by the charged-particle microscope 302 and that is known or expected to be non-destructive with respect to all, most, many, or any suitable subset of whatever population of specimens that the charged-particle microscope 302 might potentially encounter in clinical, scientific, or laboratory fields. In other words, the default microscopy protocol can be any suitable microscopy scan in which any of the configurable operating settings of the charged-particle microscope 302 are set, changed, or adjusted to any suitable default values or states that are known or expected to be safe for wide swaths of potential or possible specimens. As some non-limiting examples, the default microscopy protocol can involve a beam current setting, a beam voltage setting, and a stage temperature setting of the charged-particle microscope 302 being set, changed, or adjusted to any suitable default amperage, voltage, and temperature values that are known or expected to not damage, harm, or deteriorate most potential specimens. For instance, the beam voltage, beam current, and stage temperature of the default microscopy protocol can be set, changed, or adjusted to whatever low, threshold, or otherwise non-extreme values are widely recognized to not harm many specimens (e.g., if it is known or expected that most or many different types of specimens are not harmed by beam voltages below 10 kV, then the default microscopy protocol can have a beam voltage setting that is set to any suitable value below 10 kV; if it is known or expected that most or many different types of specimens are not harmed by beam currents below 0.1 nA, then the default microscopy protocol can have a beam current setting that is set to any suitable value below 0.1 nA; if it is known or expected that most or many different types of specimens are not harmed by stage temperatures of 300 Kelvin (K), then the default microscopy protocol can have a stage temperature setting that is set to 300 K).

In various instances, such scanning can instead be in accordance with any suitable microscopy protocol that is defined or otherwise selected by a user or technician of the charged-particle microscope 302. As a non-limiting example, the user or technician can select (e.g., via any suitable user-interface devices of the charged-particle microscope 302 or of an associated computerized workstation) any suitable values or states for any of the configurable operating settings of the charged-particle microscope 302, and the charged-particle microscope 302 can accordingly scan the specimen 304 using such selected values or states.

In any case, such scanning can yield or otherwise result in the scanned image 402. In various instances, the scanned image 402 can visually depict or illustrate the specimen 304, or any portion thereof, in any suitable fashion. In some cases, the scanned image 402 can be an x-by-y array of pixels, for any suitable positive integers x and y. In other cases, the scanned image 402 can be an x-by-y-by-z array of voxels, for any suitable positive integers x, y, and z. In various aspects, the visual qualities or appearance (e.g., brightness, contrast, resolution, colors) of the scanned image 402 can vary with or otherwise depend upon the microscopy protocol (e.g., default or user-selected) that is implemented by the charged-particle microscope 302 (e.g., can depend upon the default or user-selected values or states of the configurable operating settings that the charged-particle microscope 302 uses to scan the specimen 304). As a non-limiting example, the default microscopy protocol can be any suitable type of backscattered electron detection (BSE) scan. In such case, the scanned image 402 can be considered as capturing, conveying, or otherwise representing various crystallographic, topographic, or magnetic field information regarding the specimen 304. As another non-limiting example, the default microscopy protocol can be any suitable type of electron backscatter diffraction (EBSD) scan. In such case, the scanned image 402 can be considered as capturing, conveying, or otherwise representing various crystalline structure or orientation information regarding the specimen 304. As even another non-limiting example, the default microscopy protocol can be any suitable cathodoluminescence scan. In such case, the scanned image 402 can be considered as capturing, conveying, or otherwise representing high-resolution topographic information regarding luminescent portions (if any) of the specimen 304.

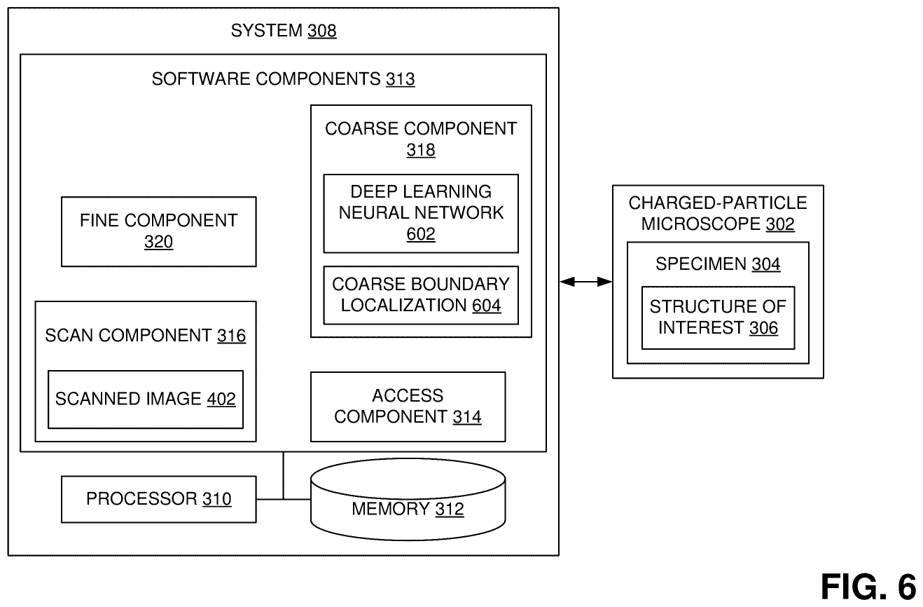

FIG. 6 illustrates a block diagram of an example, non-limiting system including a deep learning neural network and a coarse boundary localization that can facilitate edge localization via intelligent insertion of image processing calipers in accordance with one or more embodiments described herein.

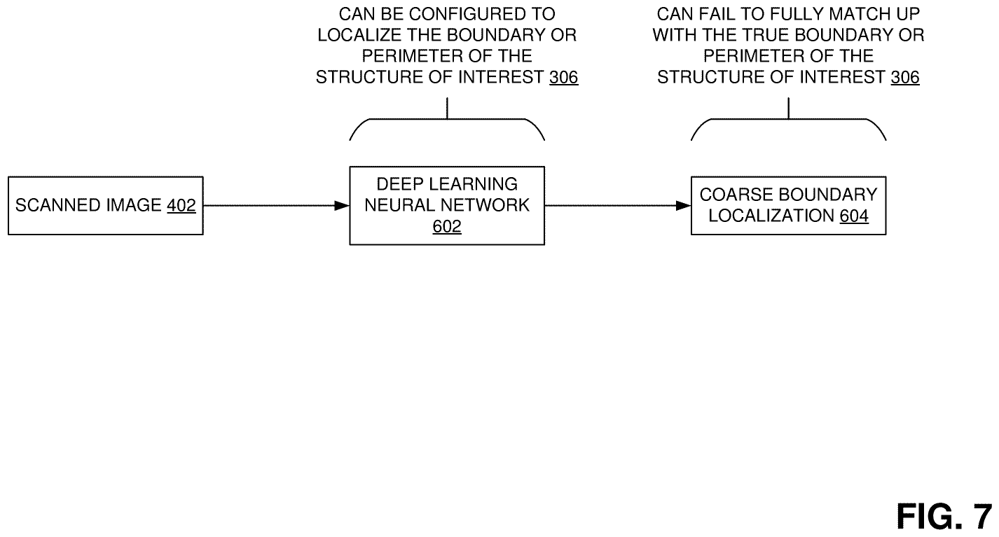

In various embodiments, the coarse component 318 can electronically store, electronically maintain, electronically control, or otherwise electronically access a deep learning neural network 602. In various aspects, the coarse component 318 can leverage the deep learning neural network 602, so as to generate a coarse boundary localization 604. Non-limiting details are described with respect to FIG. 7.

FIG. 7 illustrates an example, non-limiting block diagram showing how the coarse boundary localization 604 can be obtained in accordance with one or more embodiments described herein.

In various aspects, the deep learning neural network 602 can exhibit any suitable deep learning internal architecture. Indeed, in various cases, the deep learning neural network 602 can have an input layer, one or more hidden layers, and an output layer. In various instances, any of such layers can be coupled together by any suitable interneuron connections or interlayer connections, such as forward connections, skip connections, or recurrent connections. Furthermore, in various cases, any of such layers can be any suitable types of neural network layers having any suitable learnable or trainable internal parameters. For example, any of such input layer, one or more hidden layers, or output layer can be convolutional layers, whose learnable or trainable parameters can be convolutional kernels. As another example, any of such input layer, one or more hidden layers, or output layer can be dense layers, whose learnable or trainable parameters can be weight matrices or bias values. As still another example, any of such input layer, one or more hidden layers, or output layer can be batch normalization layers, whose learnable or trainable parameters can be shift factors or scale factors. As even another example, any of such input layer, one or more hidden layers, or output layer can be LSTM layers, whose learnable or trainable parameters can be input-state weight matrices or hidden-state weight matrices. As yet another example, any of such input layer, one or more hidden layers, or output layer can be transformer layers, whose learnable or trainable parameters can be single-head or multi-head attention blocks or other weight matrices. Further still, in various cases, any of such layers can be any suitable types of neural network layers having any suitable fixed or non-trainable internal parameters. For example, any of such input layer, one or more hidden layers, or output layer can be non-linearity layers, padding layers, pooling layers, or concatenation layers. In some non-limiting embodiments, the deep learning neural network 602 can be any suitable foundational model that has not undergone any context-specific or deployment-specific fine-tuning.

Regardless of the specific internal architecture (e.g., the specific numbers, types, or organizations of layers) that is implemented within the deep learning neural network 602, the deep learning neural network 602 can be configured as an edge localizer. That is, the deep learning neural network 602 can be configured to receive as input an image and to produce as output a localization that indicates where in that inputted image an edge or boundary of any given structure of interest is located.

Accordingly, the coarse component 318 can utilize the deep learning neural network 602 to electronically generate the coarse boundary localization 604. In particular, the coarse component 318 can electronically execute the deep learning neural network 602 on the scanned image 402. In various cases, such execution can cause the deep learning neural network 602 to produce the coarse boundary localization 604. More specifically, the coarse component 318 can feed the scanned image 402 to the input layer of the deep learning neural network 602. In various aspects, the scanned image 402 can complete a forward pass through the one or more hidden layers of the deep learning neural network 602. In various instances, the output layer of the deep learning neural network 602 can compute or otherwise calculate the coarse boundary localization 604, based on activation maps or feature maps provided by the one or more hidden layers of the deep learning neural network 602.

In any case, the coarse boundary localization 604 can be any suitable electronic data that indicates, conveys, specifies, or otherwise represents where (in the opinion of the deep learning neural network 602) an outer-most edge or boundary of the structure of interest 306 is located within the scanned image 402 and thus within the specimen 304. More specifically, the coarse boundary localization 604 can be one or more scalars, one or more vectors, one or more matrices, one or more tensors, or any suitable combination thereof that indicates or otherwise represents an intra-image location within the scanned image 402 of an outer perimeter of the structure of interest 306. As a non-limiting example, the coarse boundary localization 604 can be a segmentation mask. In such case, the coarse boundary localization 604 can be a pixel-wise or voxel-wise array having the same format, size, or dimensionality as the scanned image 402 that indicates which pixels or voxels of the scanned image 402 are inferred to belong to the outer perimeter of the structure of interest 306 and which pixels or voxels of the scanned image 402 are inferred to not belong to the outer perimeter.

For instance, suppose that the scanned image 402 is an x-by-y pixel array. In such case, the coarse boundary localization 604 can be an x-by-y array, each numerical element of which can take on either: a first value indicating membership of the edge of the structure of interest 306; or a second value indicating non-membership of the edge of the structure of interest 306. That is, for any suitable positive integers i≤x and j≤y, an element (i, j) of the coarse boundary localization 604 having or exhibiting the first value can be interpreted to mean that the deep learning neural network 602 has concluded or predicted that a pixel (i, j) of the scanned image 402 belongs to or is otherwise a constituent part of the outer perimeter, edge, or boundary of the structure of interest 306. In contrast, the element (i, j) of the coarse boundary localization 604 instead having or exhibiting the second value can be interpreted to mean that the deep learning neural network 602 has concluded or predicted that the pixel (i, j) of the scanned image 402 does not belong to or is otherwise not a constituent part of the outer perimeter, edge, or boundary of the structure of interest 306.

As another instance, suppose that the scanned image 402 is an x-by-y-by-z voxel array. In such case, the coarse boundary localization 604 can be an x-by-y-by-z array, each numerical element of which can take on either: the first value indicating membership of the edge of the structure of interest 306; or the second value indicating non-membership of the edge of the structure of interest 306. That is, for any suitable positive integers i≤x, j≤y, and k≤z, an element (i, j, k) of the coarse boundary localization 604 having or exhibiting the first value can be interpreted to mean that the deep learning neural network 602 has concluded or predicted that a voxel (i, j, k) of the scanned image 402 belongs to or is otherwise a constituent part of the outer perimeter, edge, or boundary of the structure of interest 306. In contrast, the element (i, j, k) of the coarse boundary localization 604 instead having or exhibiting the second value can be interpreted to mean that the deep learning neural network 602 has concluded or predicted that the voxel (i, j, k) of the scanned image 402 does not belong to or is otherwise not a constituent part of the outer perimeter, edge, or boundary of the structure of interest 306.

Thus, the deep learning neural network 602 can be considered as labeling or classifying each pixel or voxel of the scanned image 402 either as being a part of the perimetral edge or boundary of the structure of interest 306 or instead as not being a part of the perimetral edge or boundary of the structure of interest 306.

In various embodiments, no matter how extensively the deep learning neural network 602 is trained, the deep learning neural network 602 can nevertheless be vulnerable to localization inaccuracy. In particular, due to the statistical and aggregatory character of deep learning training, the deep learning neural network 602 can be prone to at least some non-zero amount of edge overshooting or edge undershooting. In various aspects, the structure of interest 306 can be considered as having a true perimetral edge or boundary. In various instances, edge overshooting can be considered as the deep learning neural network 602 inferring that such true perimetral edge or boundary extends farther than it actually does. In other words, edge overshooting can occur when the deep learning neural network 602 mistakenly infers that certain pixels or voxels belong to the perimetral edge or boundary of the structure of interest 306 when those certain pixels or voxels do not actually belong to structure of interest 306 at all. Conversely, edge undershooting can be considered as the deep learning neural network 602 inferring that the true perimetral edge or boundary does not extend as far as it actually does. In other words, edge undershooting can occur when the deep learning neural network 602 mistakenly infers that certain pixels or voxels belong to the perimetral edge or boundary of the structure of interest 306 when those certain pixels or voxels instead actually belong to or make up the interior of the structure of interest 306. In any case, the coarse boundary localization 604 can thus fail to be coextensive with or to fully match up with the true edge, boundary, or perimeter of the structure of interest 306. In view of this inaccuracy, the term “coarse” can be considered as appropriate.

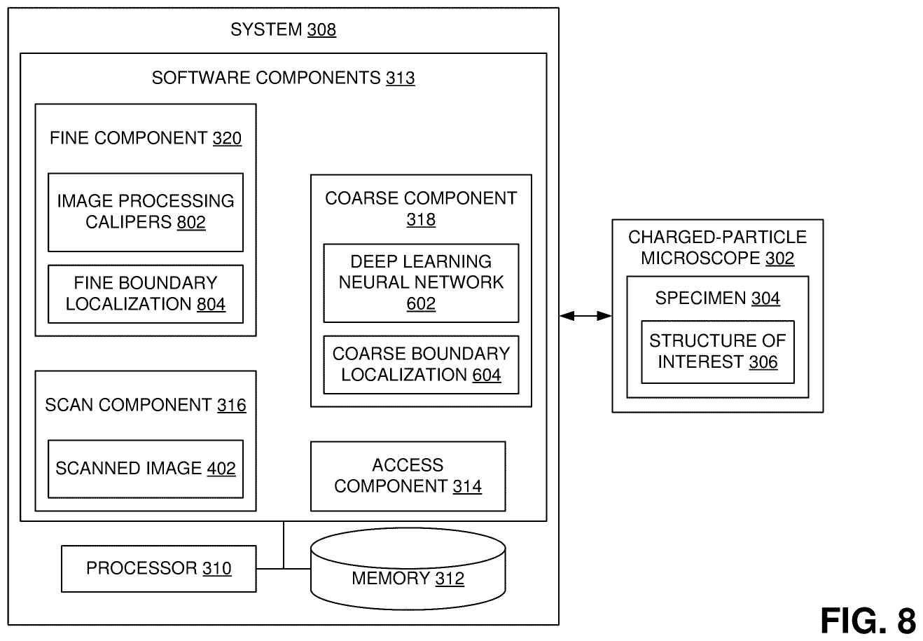

FIG. 8 illustrates a block diagram of an example, non-limiting system including a set of image processing calipers and a fine boundary localization that can facilitate edge localization via intelligent insertion of image processing calipers in accordance with one or more embodiments described herein.

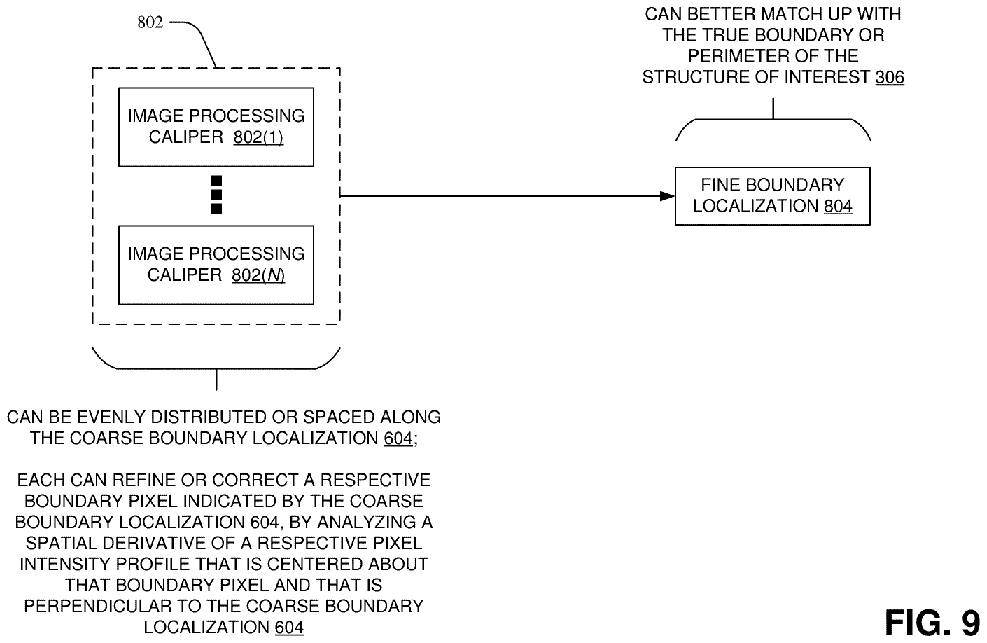

In various embodiments, the fine component 320 can electronically store, electronically maintain, electronically control, or otherwise electronically access a plurality of image processing calipers 802. In various aspects, the fine component 320 can leverage both the plurality of image processing calipers 802 and the coarse boundary localization 604, so as to generate a fine boundary localization 804. Non-limiting details are described with respect to FIG. 9.

FIG. 9 illustrates an example, non-limiting block diagram showing how the plurality of image processing calipers 802 can obtain the fine boundary localization 804 in accordance with one or more embodiments described herein.

In various embodiments, the plurality of image processing calipers 802 can comprise n calipers, for any suitable positive integer n: an image processing caliper 802(1) to an image processing caliper 802(n). In various aspects, each of the plurality of image processing calipers 802 can be any suitable computer vision algorithm, computer vision technique, or computer vision program application that can electronically detect or otherwise electronically identify an edge or boundary within any given image. In particular, an image processing caliper can be considered as interpreting a significant change or transition in intensity or color of a given image as being indicative of the presence of an edge or boundary. On the other hand, an image processing caliper can be considered as interpreting gradually changing or unchanging intensity or color as instead being indicative of the absence of an edge or boundary. As a non-limiting example, an image processing caliper can be, comprise, include, or otherwise utilize an electronic Sobel operator, which can use convolutions of Sobel kernels to compute gradient magnitude and direction, thereby identifying intra-image regions having significant or stark intensity changes. As another non-limiting example, an image processing caliper can be, comprise, include, or otherwise utilize an electronic Prewitt operator, which can use convolutions of Prewitt kernels to identify intra-image regions of high intensity changes. As yet another non-limiting example, an image processing caliper can be, comprise, include, or otherwise utilize an electronic canny edge detector, which can use smoothening via a Gaussian filter and edge tracing via hysteresis to detect edges. As even another non-limiting example, an image processing caliper can be, comprise, include, or otherwise utilize an electronic Laplacian of Gaussian (LoG) detector, which can use smoothening via the Laplace operator to detect edges. As still another non-limiting example, an image processing caliper can be, comprise, include, or otherwise utilize an electronic Roberts Cross operator, which can use pairs of specific convolutional kernels to detect edges. In a non-limiting, example embodiment, an image processing caliper can detect an edge or boundary along a respective or given pixel (or voxel) intensity profile, by analyzing a spatial derivative of that intensity profile. Specifically, the intensity profile can be whatever intensity values are exhibited by some given straight, contiguous line or chain of pixels or voxels, the image processing caliper can determine the pixel or voxel location index at which that intensity profile exhibits more than any suitable threshold amount of intensity change or intensity transition, and such pixel or voxel location index can be considered as being the location of an edge or boundary.

In various aspects, the fine boundary localization 804 can be any suitable electronic data that indicates, conveys, specifies, or otherwise represents where the outer-most edge or boundary of the structure of interest 306 is located within the scanned image 402 and thus within the specimen 304. Accordingly, the fine boundary localization 804 can be one or more scalars, one or more vectors, one or more matrices, one or more tensors, or any suitable combination thereof that indicates or otherwise represents an intra-image location within the scanned image 402 of the outer perimeter of the structure of interest 306. In various instances, the fine boundary localization 804 can have the same format, size, or dimensionality as the coarse boundary localization 604. For example, if the coarse boundary localization 604 is a segmentation mask indicating which pixels or voxels of the scanned image 402 belong to the edge or boundary of the structure of interest 306 and which pixels or voxels do not, then the fine boundary localization 804 can likewise be a segmentation mask indicating which pixels or voxels of the scanned image 402 belong to the edge or boundary of the structure of interest 306 and which pixels or voxels do not.

In various aspects, because the fine boundary localization 804 can be produced by the plurality of image processing calipers 802 whereas the coarse boundary localization 604 can instead be produced by the deep learning neural network 602, the fine boundary localization 804 can exhibit more accuracy or reliability than the coarse boundary localization 604. In other words, the fine boundary localization 804 can be considered as more fully matching up with the true perimetral edge or boundary of the structure of interest 306 than the coarse boundary localization 604, hence the term “fine.” Indeed, unlike the deep learning neural network 602, none of the plurality of image processing calipers 802 can be prone to edge overshooting or edge undershooting. This can be due to the fact that none of the plurality of image processing calipers 802 are created via statistical or aggregatory training techniques that cause edge detection or localization performance to become averaged across different pixel or voxel patterns. Instead, each of the plurality of image processing calipers 802 can, as explained above, be considered as an explicit computational operator or an explicit sequence of computational operators that detects edges or boundaries by examining the gradients or rates of change of pixel or voxel intensity values.

As a specific, non-limiting example of how the fine boundary localization 804 can be generated, each of the plurality of image processing calipers 802 can compute any suitable spatial derivative of or along a respective pixel or voxel intensity profile, and the fine component 320 can electronically insert or place the plurality of image processing calipers 802 into the scanned image 402, such that the plurality of image processing calipers 802 are positioned around or along the inferred edge or boundary indicated by the coarse boundary localization 604.

More specifically, the inferred edge or boundary indicated by the coarse boundary localization 604 can be considered as a closed path or loop. In various aspects, any given image processing caliper of the plurality of image processing calipers 802 can be inserted or placed into the scanned image 402, such that the given image processing caliper intersects with that closed path or loop at some respective location around or along that closed path or loop. In other words, the given image processing caliper can be considered as analyzing or evaluating a spatial derivative (e.g., a first-order derivative, a second-order derivative, a third-order derivative) of intensity values exhibited by a straight line or chain of pixels or voxels, where that straight line or chain of pixels or voxels intersects with or otherwise crosses that closed path or loop. For example, suppose that the closed path or loop includes a pixel (i, j). In such case, the straight line or chain of pixels can also include the pixel (i, j), such that the straight line or chain of pixels can be considered as intersecting with or crossing the closed path or loop at the pixel (i, j). In some instances, the straight line or chain of pixels or voxels can be oriented orthogonally or perpendicularly to that closed path or loop. In other instances, that straight line or chain of pixels or voxels can be oriented substantially orthogonally or perpendicularly to that closed path or loop (e.g., such that the straight line or chain of pixels or voxels is within any suitable threshold margin of being orthogonal or perpendicular to that closed path or loop). In various cases, that straight line or chain of pixels or voxels can be bisected by that closed path or loop. In other words, that straight line or chain of pixels or voxels can be centered on or about that closed path or loop, such that one half of that straight line or chain of pixels or voxels is inside of that closed path or loop (e.g., is in an image region that is circumscribed by that closed path or loop), and such that another half of that straight line or chain of pixels or voxels is outside of that closed path or loop (e.g., is in an image region that is not circumscribed by that closed path or loop). To continue the above example where the straight line or chain of pixels intersects with the closed path or loop at the pixel (i, j), the straight line or chain of pixels being bisected by the closed path or loop can mean that the pixel (i, j) is the center point of that straight line or chain of pixels. However, in other cases, that straight line or chain of pixels or voxels need not be bisected by that closed path or loop (e.g., more or less than half of that straight line or chain of pixels or voxels can be inside of that closed path; more or less than half of that straight line or chain of pixels or voxels can be outside of that closed path or loop).

No matter how that straight line or chain of pixels or voxels is specifically oriented with respect to or positioned on that closed path or loop, the following can apply: one or more first pixels or voxels that are on that straight line or chain can be considered as being members of that closed path or loop (e.g., can be indicated by the coarse boundary localization 604 as belonging to the inferred edge or boundary of the structure of interest 306); one or more second pixels or voxels that are on that straight line or chain can be considered as being positioned on an interior side of that closed path or loop (e.g., as being inside of the structure of interest 306); and one or more third pixels or voxels of that straight line or chain can be considered as being positioned on an exterior side of that closed path or loop (e.g., as being outside of the structure of interest 306). In various aspects, the given image processing caliper can compute a spatial intensity derivative of any order (e.g., a first-order spatial intensity derivative can be equal to the change in intensity divided by change in pixel or voxel distance; a second-order spatial intensity derivative can be equal to the change in rate of change of intensity divided by change in pixel or voxel distance) for each pixel or voxel in that straight line or chain of pixels or voxels, and the given image processing caliper can localize an edge or boundary on that straight line or chain of pixels or voxels by comparing those computed spatial intensity derivatives to any suitable threshold magnitude.

If the absolute value of the spatial intensity derivative of any of the one or more first pixels or voxels satisfies (e.g., is greater than) the threshold magnitude, this can indicate that the given image processing caliper has detected an edge or boundary at a same intra-image location at which the deep learning neural network 602 inferred that there was an edge or boundary. In other words, this can mean that the deep learning neural network 602 correctly classified the one or more first pixels as belonging to the edge or boundary of the structure of interest 306. In such situations, the fine component 320 can cause the one or more first pixels or voxels, which are indicated in the coarse boundary localization 604 as belonging to the edge or boundary of the structure of interest 306, to likewise be indicated in the fine boundary localization 804 as belonging to the edge or boundary of the structure of interest 306.

In contrast, if none of the one or more first pixels or voxels has a spatial intensity derivative whose absolute value satisfies the threshold magnitude, this can indicate that the given image processing caliper has not detected an edge or boundary at an intra-image location at which the deep learning neural network 602 inferred that there was an edge or boundary. That is, this can mean that the deep learning neural network 602 incorrectly classified the one or more first pixels as belonging to the edge or boundary of the structure of interest 306. In such situations, the fine component 320 can cause the one or more first pixels or voxels, which are indicated in the coarse boundary localization 604 as belonging to the edge or boundary of the structure of interest 306, to be indicated in the fine boundary localization 804 as not belonging to the edge or boundary of the structure of interest 306.

Indeed, if none of the one or more first pixels or voxels has a spatial intensity derivative whose absolute value satisfies the threshold magnitude, but if the absolute value of the spatial intensity derivative of any of the one or more second pixels or voxels satisfies the threshold value, this can indicate that the deep learning neural network 602 overshot the edge or boundary of the structure of interest 306, at least along the straight line or chain of pixels or voxels analyzed by the given image processing caliper. In other words, this can mean that some pixels or voxels which actually or truly do not even belong to the structure of interest 306 were incorrectly classified by the deep learning neural network 602 as belonging to the edge or boundary of the structure of interest 306. In such situations, the fine component 320 can cause whichever of the one or more second pixels or voxels, which are indicated in the coarse boundary localization 604 as not belonging to the edge or boundary of the structure of interest 306, whose absolute value of spatial intensity derivative satisfies the threshold to be indicated in the fine boundary localization 804 as belonging to the edge or boundary of the structure of interest 306. This can be considered as an incremental refinement or update made to the coarse boundary localization 604.

On the other hand, if none of the one or more first pixels or voxels has a spatial intensity derivative whose absolute value satisfies the threshold magnitude, but if the spatial intensity derivative of any of the one or more third pixels or voxels has an absolute value that satisfies the threshold magnitude, this can indicate that the deep learning neural network 602 undershot the edge or boundary of the structure of interest 306, at least along the straight line or chain of pixels or voxels analyzed by the given image processing caliper. In other words, this can mean that some pixels or voxels which actually or truly belong to an interior region of the structure of interest 306 were incorrectly classified by the deep learning neural network 602 as belonging to the edge or boundary of the structure of interest 306. In such situations, the fine component 320 can cause whichever of the one or more third pixels or voxels, which are indicated in the coarse boundary localization 604 as not belonging to the edge or boundary of the structure of interest 306, whose absolute value of spatial intensity derivative satisfies the threshold to be indicated in the fine boundary localization 804 as belonging to the edge or boundary of the structure of interest 306. As above, this can be considered as an incremental refinement or update made to the coarse boundary localization 604.

In some cases where none of the one or more first pixels or voxels has a spatial derivative whose absolute value satisfies the threshold magnitude, it is possible that multiple ones of the one or more second pixels or voxels or multiple ones of the one or more third pixels or voxels have spatial intensity derivatives whose absolute values satisfy the threshold magnitude. In such cases, the fine component 320 can cause the fine boundary localization 804 to indicate as belonging to the edge or boundary of the structure of interest 306 whichever of those multiple satisfactory pixels or voxels is spatially closed or nearest to the one or more first pixels or voxels. However, it should be appreciated that spatial proximity is a mere non-limiting example of a disambiguation technique that can be implemented in various embodiments. In various instances, any other suitable disambiguation technique can be implemented.

In various aspects, each of the plurality of image processing calipers 802 can thus be considered as either preserving or incrementally refining the coarse boundary localization 604 (e.g., some portions or segments of the coarse boundary localization 604 can be validated by respective image processing calipers and can thus be preserved; other portions or segments of the coarse boundary localization 604 can be invalidated by respective image processing calipers and can thus be incrementally refined). In various instances, the final or collective result or product of such preservation or incremental refinement can be considered as the fine boundary localization 804.

Note that the above description regarding how any given image processing caliper can leverage spatial derivatives of intensity values to detect edges or boundaries provides mere non-limiting examples. It should be appreciated that any image processing caliper can detect edges or boundaries by examining or analyzing any suitable combination of: pixel/voxel intensity values; or spatial derivatives of any suitable order of pixel/voxel intensity values.

Furthermore, note that, in some embodiments, the performance of any given image processing caliper can be improved or made more reliable by first applying any suitable filtration technique to whatever straight line or chain of pixels/voxels that the given image processing caliper analyzes. As a non-limiting example, the ability of the given image processing caliper to correctly identify or localize an edge along that straight line or chain of pixels/voxels can be heightened by first applying any suitable denoising technique to the intensity values of that straight line or chain of pixels/voxels In such case, the given image processing caliper would be considered as analyzing a denoised version of the intensity values exhibited by that straight line or chain of pixels/voxels. As another non-limiting example, the ability of the given image processing caliper to correctly identify or localize an edge along that straight line or chain of pixels/voxels can be heightened by first applying any suitable normalization technique to the intensity values of that straight line or chain of pixels/voxels. In such case, the given image processing caliper would be considered as analyzing a normalized version of the intensity values exhibited by that straight line or chain of pixels/voxels.

Further still, note that the plurality of image processing calipers 802 can, in some cases, be evenly spaced or evenly distributed along or around whatever closed path or loop is indicated by the coarse boundary localization 604. This can help to ensure that the coarse boundary localization 604 is refined in a even or proportional fashion. However, in other cases, the plurality of image processing calipers 802 can be unevenly spaced or unevenly distributed along or around that closed path or loop.

Furthermore, in various aspects, any two image processing calipers that are adjacent or consecutive with each other around or along that closed path or loop can be separated by one or more intervening or intermediary pixels or voxels. This can help to reduce a computational footprint involved in computing the fine boundary localization 804.

However, in other aspects, any two image processing calipers that are adjacent or consecutive with each other around or along that closed path or loop can instead be separated by no intervening or intermediary pixels or voxels. This can help to even further increase an accuracy or reliability of the fine boundary localization 804.

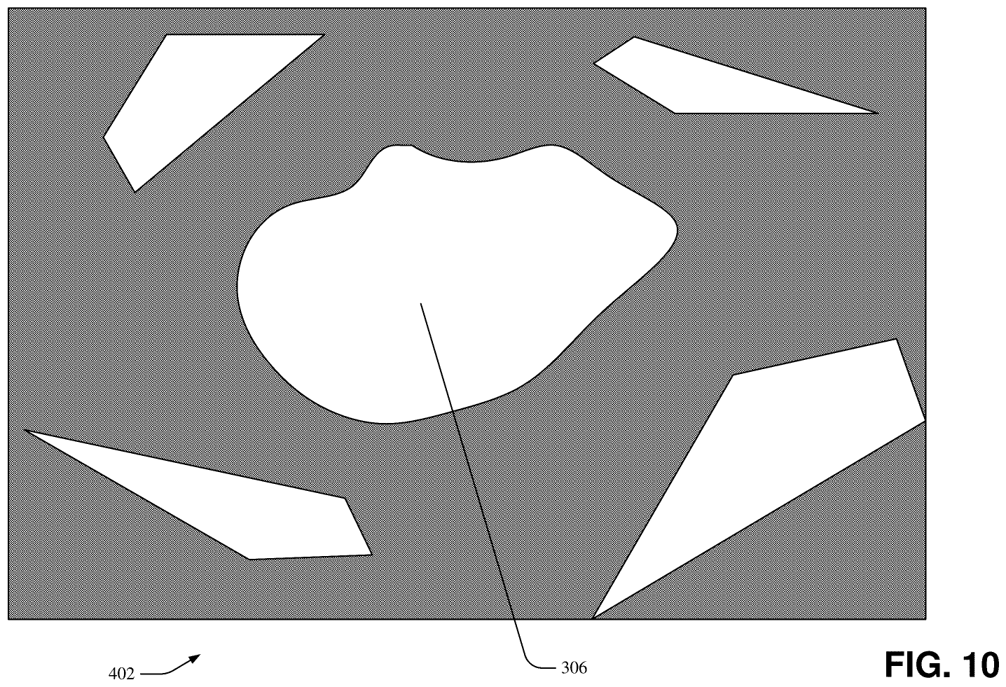

In any case, insertion of the plurality of image processing calipers 802 along or around whatever inferred boundary or edge is indicated by the coarse boundary localization 604 can yield the fine boundary localization 804. For clarification, consider FIGS. 10-16.

FIGS. 10-16 illustrate example, non-limiting dramatizations that clarify one or more embodiments described herein.

FIG. 10 shows a non-limiting example dramatization of the scanned image 402. As shown, the scanned image 402 can depict various sharp or angular objects, as well as a rounder, amorphous object. In various instances, that rounder, amorphous object can, in the non-limiting examples of the figures, be considered or otherwise treated as the structure of interest 306.

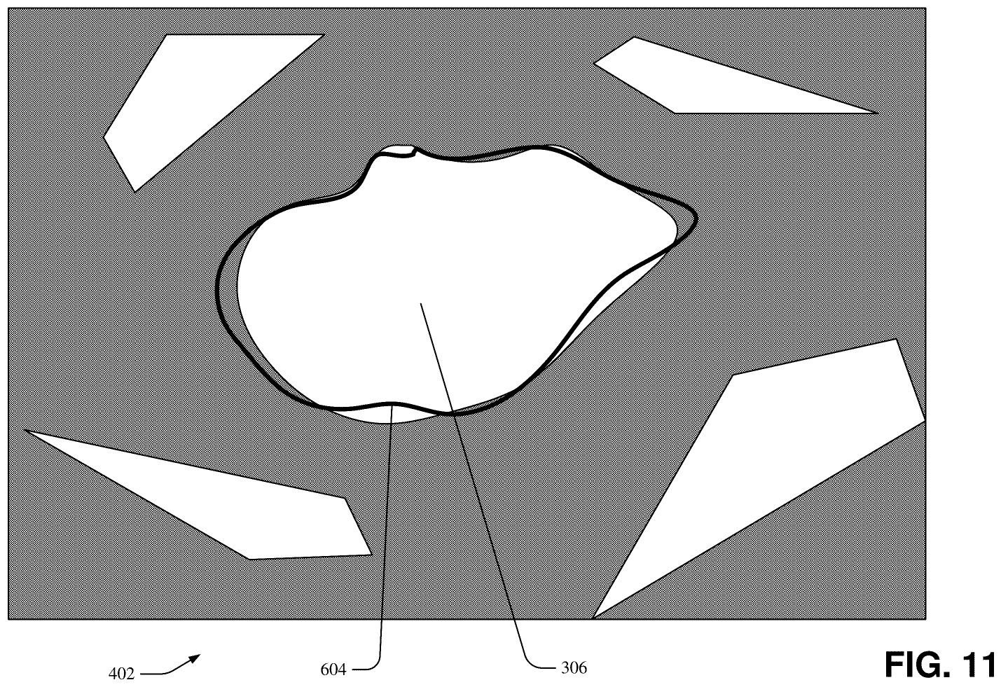

FIG. 11 illustrates a non-limiting example dramatization of the coarse boundary localization 604. In particular, the deep learning neural network 602 can be executed on the non-limiting example of the scanned image 402, and such execution can yield the non-limiting example of the coarse boundary localization 604. As explained above, the coarse boundary localization 604 can be considered as indicating which specific pixels are inferred or predicted to belong to the perimetral edge or boundary of the structure of interest 306. As shown, the coarse boundary localization 604 can be at least somewhat inaccurate. Indeed, although some pixels indicated by the coarse boundary localization 604 actually do belong to the perimetral edge or boundary of the structure of interest 306, other pixels indicated by the coarse boundary localization 604 do not actually belong to the perimetral edge or boundary of the structure of interest 306. For example, some pixels that are actually outside of the structure of interest 306 are incorrectly indicated by the coarse boundary localization 604 as belonging to the perimetral edge of boundary of the structure of interest 306.

These can be considered as instances of overshooting by the deep learning neural network 602. As another example, other pixels that are actually inside of the structure of interest 306 are incorrectly indicated by the coarse boundary localization 604 as belonging to the perimetral edge of boundary of the structure of interest 306. These can be considered as instances of undershooting by the deep learning neural network 602.

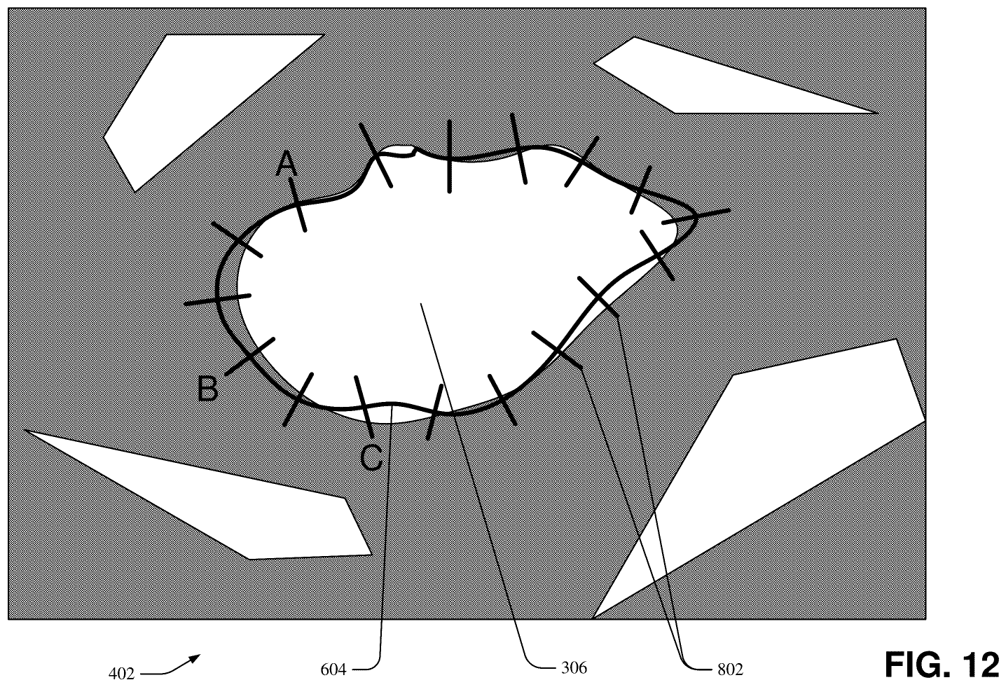

FIG. 12 illustrates a non-limiting example dramatization of the plurality of image processing calipers 802. As shown, the plurality of image processing calipers 802 can be inserted or placed around or along the coarse boundary localization 604.

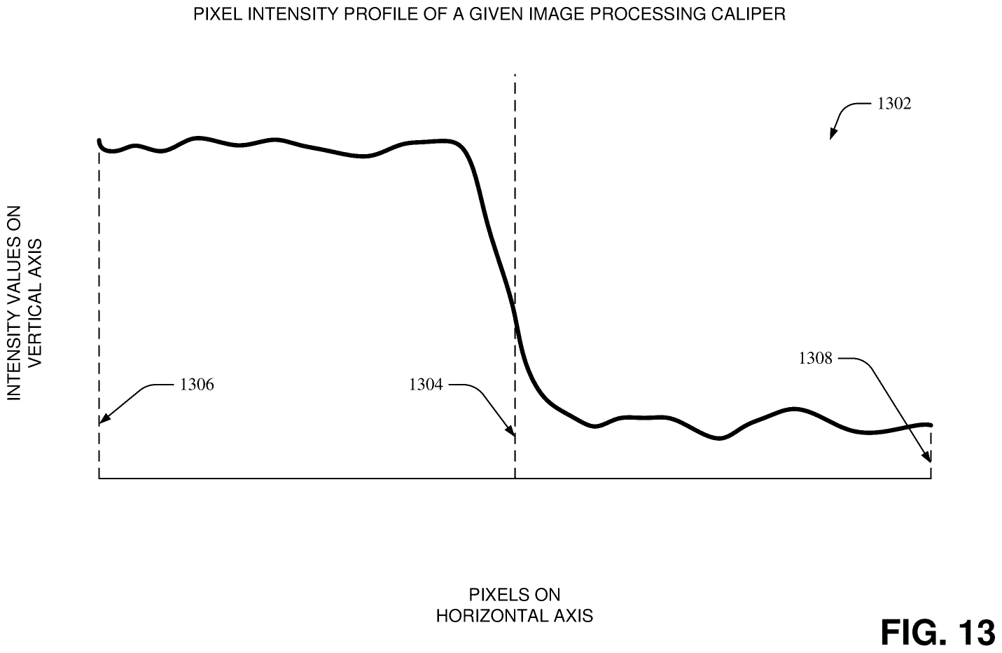

As also shown, each image processing caliper can be considered as extending along a respective straight, contiguous line of pixels that intersects with or crosses over the coarse boundary localization 604. In particular, the non-limiting example of FIG. 12 shows each of the plurality of image processing calipers 802 as being substantially orthogonal or perpendicular to the coarse boundary localization 604 and as being substantially bisected by (or centered on) the coarse boundary localization 604. In any case, each image processing caliper can be considered as analyzing the spatial derivative of its respective straight, contiguous line of pixels. Non-limiting aspects are described with respect to FIGS. 13-15.

First, consider FIG. 13. FIG. 13 shows a pixel intensity profile 1302 that can be analyzed or evaluated by a given image processing caliper. The abscissa (e.g., horizontal axis) of the pixel intensity profile 1302 can represent the straight, contiguous line of pixels of the given image processing caliper. The ordinate (e.g., vertical axis) of the pixel intensity profile 1302 can instead represent the intensity values exhibited by each pixel of that straight, contiguous line of pixels. Numeral 1304 can be considered indicating which specific pixel along that straight, contiguous line of pixels is in the coarse boundary localization 604. In other words, numeral 1304 can be considered as indicating which pixel along that straight, contiguous line of pixels was inferred by the deep learning neural network 602 as belonging to the perimetral edge or boundary of the structure of interest 306. As mentioned above, that straight, contiguous line of pixels can be bisected by or centered on the coarse boundary localization 604. For this reason, the numeral 1304 can be considered as being the center or midpoint of that straight, contiguous line of pixels (e.g., as being in the center of the horizontal pixel axis). Numeral 1306 can be considered as indicating a most-inward pixel of that straight line of pixels (e.g., as indicating which pixel that lies on that straight, contiguous line of pixels is most or farthest inside of the structure of interest 306). In contrast, numeral 1308 can be considered as indicating a most-outward pixel of that straight, contiguous line of pixels (e.g., as indicating which pixel that lies on that straight, contiguous line of pixels is most or farthest outside of the structure of interest 306). In the non-limiting example of FIG. 13, higher intensity values can indicate light colors from the scanned image 402, whereas lower intensity values can indicate darker colors from the scanned image 402. As shown in the non-limiting example of FIG. 13, the pixel intensity profile 1302 exhibits more than a threshold magnitude of slope or spatial derivative at the pixel denoted by numeral 1304. This can be interpreted to mean that the coarse boundary localization 604 correctly indicates that whatever pixel is denoted by numeral 1304 belongs to the perimetral edge or boundary of the structure of interest 306. In other words, this can mean that the given image processing caliper has validated or verified the inference of the deep learning neural network 602, at least at the specific pixel denoted by numeral 1304. Referring back to FIG. 12, the specific image processing caliper that is denoted by “A” can be considered as a non-limiting example of an image processing caliper whose pixel intensity profile might resemble the pixel intensity profile 1302.

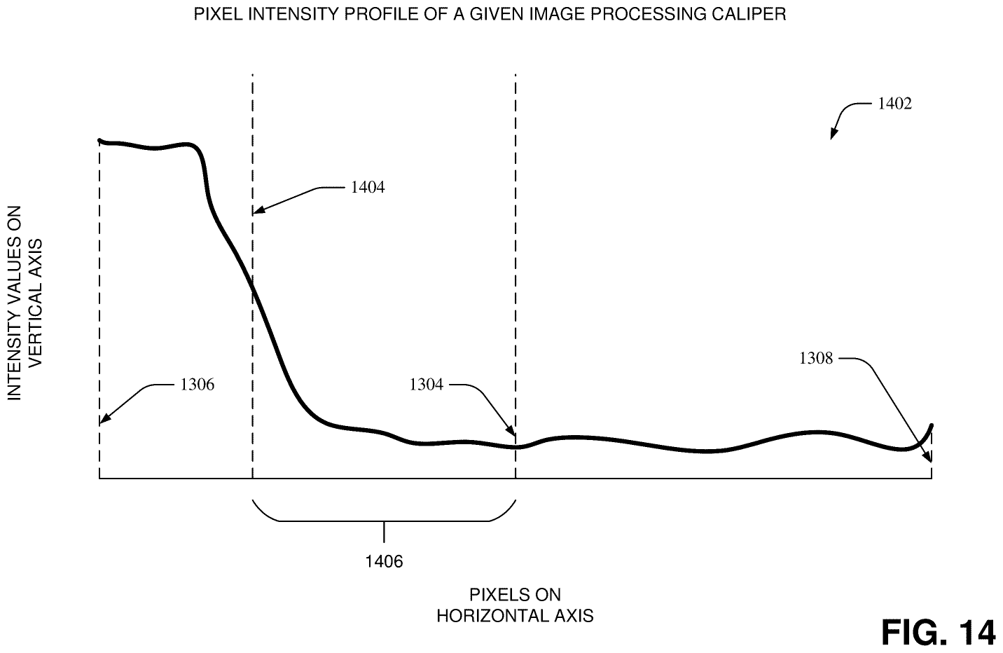

Next, consider FIG. 14. FIG. 14 shows a pixel intensity profile 1402 that can be analyzed or evaluated by a given image processing caliper. As above, the abscissa of the pixel intensity profile 1402 can represent the straight, contiguous line of pixels of the given image processing caliper; the ordinate of the pixel intensity profile 1402 can instead represent the intensity values exhibited by each pixel of that straight, contiguous line of pixels; numeral 1304 can be considered indicating which specific pixel along that straight, contiguous line of pixels is in the coarse boundary localization 604; numeral 1306 can be considered as indicating a most-inward pixel of that straight, contiguous line of pixels; and numeral 1308 can be considered as indicating a most-outward pixel of that straight, contiguous line of pixels. Now, as shown in the non-limiting example of FIG. 14, the pixel intensity profile 1402 exhibits more than a threshold magnitude of slope or spatial derivative not at the pixel denoted by numeral 1304, but instead at the pixel denoted by numeral 1404. This can be interpreted to mean that the coarse boundary localization 604 incorrectly indicates that whatever pixel is denoted by numeral 1304 belongs to the perimetral edge or boundary of the structure of interest 306 and that, rather than indicating the pixel denoted by 1304, the coarse boundary localization 604 should instead indicate the pixel denoted by numeral 1404. Note that the pixel intensity profile 1402 can be considered as an example of edge overshooting committed by the deep learning neural network 602. After all, in the non-limiting example of FIG. 14, the deep learning neural network 602 has incorrectly indicated as belonging to the perimetral edge or boundary of the structure of interest 306 a pixel that is outside of the structure of interest 306 (e.g., a pixel that, in actuality, does not even belong to the structure of interest 306 at all). Numeral 1406 can be considered as indicating or showing an amount or extent of overshoot. In any case, the coarse boundary localization 604 can be incrementally updated or refined, such that it no longer indicates the pixel denoted by numeral 1304 and such that it instead indicates the pixel denoted by numeral 1404. Referring back to FIG. 12, the specific image processing caliper that is denoted by “B” can be considered as a non-limiting example of an image processing caliper whose pixel intensity profile might resemble the pixel intensity profile 1402.

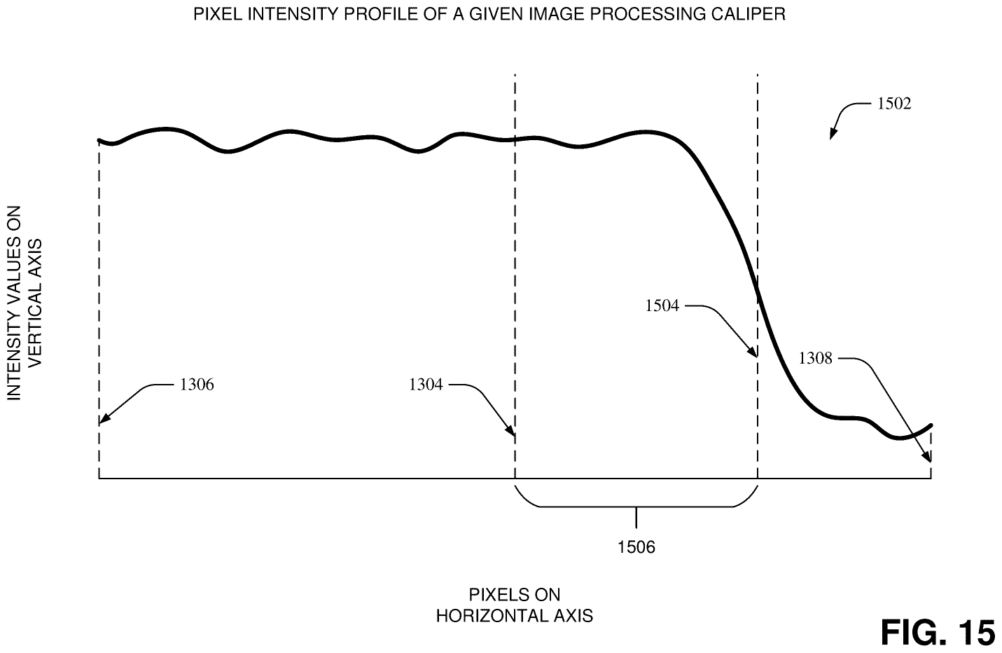

Now, consider FIG. 15. FIG. 15 shows a pixel intensity profile 1502 that can be analyzed or evaluated by a given image processing caliper. As above, the abscissa of the pixel intensity profile 1502 can represent the straight, contiguous line of pixels of the given image processing caliper; the ordinate of the pixel intensity profile 1502 can instead represent the intensity values exhibited by each pixel of that straight, contiguous line of pixels; numeral 1304 can be considered indicating which specific pixel along that straight, contiguous line of pixels is in the coarse boundary localization 604; numeral 1306 can be considered as indicating a most-inward pixel of that straight, contiguous line of pixels; and numeral 1308 can be considered as indicating a most-outward pixel of that straight, contiguous line of pixels. As shown in the non-limiting example of FIG. 15, the pixel intensity profile 1502 exhibits more than a threshold magnitude of slope or spatial derivative not at the pixel denoted by numeral 1304, but instead at the pixel denoted by numeral 1504. This can be interpreted to mean that the coarse boundary localization 604 incorrectly indicates that whatever pixel is denoted by numeral 1304 belongs to the perimetral edge or boundary of the structure of interest 306 and that, rather than indicating the pixel denoted by 1304, the coarse boundary localization 604 should instead indicate the pixel denoted by numeral 1504. Note that the pixel intensity profile 1502 can be considered as an example of edge undershooting committed by the deep learning neural network 602. After all, in the non-limiting example of FIG. 15, the deep learning neural network 602 has incorrectly indicated as belonging to the perimetral edge or boundary of the structure of interest 306 a pixel that is deep inside of the structure of interest 306 (e.g., a pixel that, in actuality, belongs to an interior of the structure of interest 306). Numeral 1506 can be considered as indicating or showing an amount or extent of undershoot. In any case, the coarse boundary localization 604 can be incrementally updated or refined, such that it no longer indicates the pixel denoted by numeral 1304 and such that it instead indicates the pixel denoted by numeral 1504. Referring back to FIG. 12, the specific image processing caliper that is denoted by “C” can be considered as a non-limiting example of an image processing caliper whose pixel intensity profile might resemble the pixel intensity profile 1502.

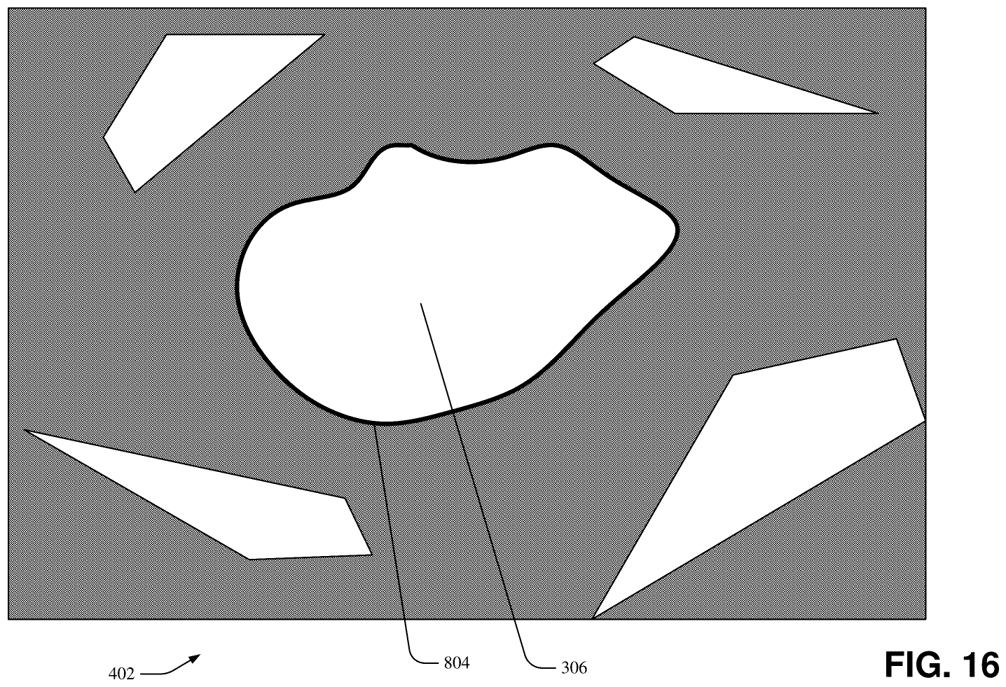

FIG. 16 illustrates a non-limiting example dramatization of the fine boundary localization 804. As shown, after the coarse boundary localization 604 has been incrementally refined (or preserved, as the case may be) by the plurality of image processing calipers 802, it can be considered or otherwise referred to as the fine boundary localization 804. As can be seen, such collective refinement can cause the fine boundary localization 804 to be more accurate (e.g., to more fully match or track the true perimetral edge or boundary of the structure of interest 306) than the coarse boundary localization 604.

Accordingly, various embodiments described herein can be considered as achieving the edge localization accuracy of image processing calipers in conjunction with the time-efficiency of deep learning. This can be accomplished by automatically inserting the plurality of image processing calipers 802 into the scanned image 402 based on the coarse boundary localization 604 produced by the deep learning neural network 602. More specifically, although the deep learning neural network 602 can be prone to edge overshooting or edge undershooting, it can nevertheless produce edge localizations that are close enough to or “in the ballpark” of the true perimetral edge or boundary of the structure of interest 306. Accordingly, by choosing image processing calipers of any suitable lengths (e.g., calipers that analyze a straight line of 100 pixels; calipers that analyze a straight line of 50 pixels; calipers that analyze a straight line of 250 pixels) and by inserting or placing those image processing calipers around or along the coarse boundary localization 604, whatever overshoot or undershoot that is committed by the deep learning neural network 602 can be rectified or resolved by those image processing calipers. Thus, the best of both worlds can be achieved by various embodiments described herein: edge localization accuracy without sacrificing edge localization convenience.

In any case, the fine component 320 can electronically generate the fine boundary localization 804 by intelligently inserting the plurality of image processing calipers 802 around or along the coarse boundary localization 604. In various embodiments, the fine component 320 can electronically inform a user or technician of the fine boundary localization 804. As a non-limiting example, the fine component 320 can electronically transmit the fine boundary localization 804 to any suitable computing device. As another non-limiting example, the fine component 320 can electronically render the fine boundary localization 804 on any suitable electronic display (e.g., on a display or screen of the charged-particle microscope 302 or of an associated computerized workstation).

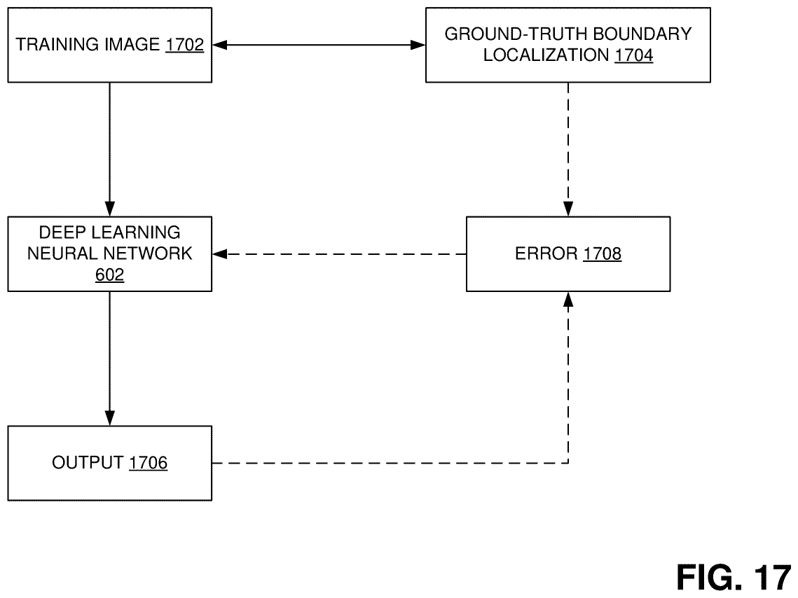

In order to maximize edge localization performance, the deep learning neural network 602 can first undergo training. A non-limiting example of such training is described with respect to FIG. 17.

FIG. 17 illustrates an example, non-limiting block diagram showing how the deep learning neural network 602 can be trained in accordance with one or more embodiments described herein.

In various aspects, prior to beginning training, the trainable internal parameters (e.g., convolutional kernels, weight matrices, bias values) of the deep learning neural network 602 can be initialized in any suitable fashion (e.g., via random initialization) by the system 308.

In various embodiments, there can be a training image 1702 and a ground-truth boundary localization 1704. In various aspects, the training image 1702 can be any suitable scanned image (e.g., having the same format, size, or dimensionality as the scanned image 402) that depicts any suitable respective structure of interest (e.g., that depicts some instantiation or version of the structure of interest 306 or of some different structure of interest). In various instances, the ground-truth boundary localization 1704 can be whatever correct or accurate edge localization (e.g., correct or accurate edge or boundary segmentation mask) that is known or deemed to correspond to the training image 1702 (e.g., can have the same format, size, or dimensionality as the set of coarse boundary localization 604).

In any case, the system 308 can cause the deep learning neural network 602 to be executed on the training image 1702, thereby causing the deep learning neural network 602 to produce an output 1706. More specifically, in some cases, the training image 1702 can be fed or routed to the input layer of the deep learning neural network 602, the training image 1702 can complete a forward pass through the one or more hidden layers of the deep learning neural network 602, and the output layer of the deep learning neural network 602 can compute the output 1706 based on activation maps or feature maps provided by the one or more hidden layers of the deep learning neural network 602.

Note that the format, size, or dimensionality of the output 1706 can be dictated by the number, arrangement, sizes, or other characteristics of the neurons, convolutional kernels, attention blocks, or other internal parameters of the output layer (or of any other layers) of the deep learning neural network 602. Accordingly, the output 1706 can be forced to have any desired format, size, or dimensionality, by adding, removing, or otherwise adjusting characteristics of the output layer (or of any other layers) of the deep learning neural network 602.

In various aspects, the output 1706 can be considered as the predicted or inferred coarse boundary localization (e.g., predicted or inferred edge or boundary segmentation mask) that the deep learning neural network 602 has synthesized based on the training image 1702. Note that, if the deep learning neural network 602 has so far undergone no or little training, then the output 1706 can be highly inaccurate. In other words, the output 1706 can be very different from the ground-truth boundary localization 1704.

In various aspects, an error 1708 (e.g., mean absolute error, mean squared error, cross-entropy error) between the output 1706 and the ground-truth boundary localization 1704 can be computed by the system 308. In various instances, the trainable internal parameters of the deep learning neural network 602 can be incrementally updated via backpropagation (e.g., stochastic gradient descent) based on the error 1708.

In various cases, such execution-and-update procedure can be repeated for any suitable number input-annotation pairs. This can ultimately cause the trainable internal parameters of the deep learning neural network 602 to become iteratively optimized for accurately performing edge localization based on inputted scanned images (although, as mentioned above, it can be impossible to completely prevent overshooting or undershooting, no matter the extent of training). In various aspects, any suitable training batch sizes, any suitable error/loss functions, or any suitable training termination criteria can be utilized during such training.

Although the herein disclosure mainly describes the deep learning neural network 602 as being trained in supervised fashion, this is a mere non-limiting example for ease of explanation and illustration. In various embodiments, any other suitable training paradigms can be used to train the deep learning neural network 602, such as unsupervised training or reinforcement learning, any of which may be federated or unfederated.

Although the herein disclosure mainly describes the fine component 320 as rendering or presenting the fine boundary localization 804 to the user or technician of the charged-particle microscope 302, these are mere non-limiting examples for ease of explanation and illustration. In various embodiments, the fine component 320 can electronically transmit the fine boundary localization 804 to any suitable computing device that is associated with the charged-particle microscope. As a non-limiting example, the fine component 320 can share the fine boundary localization 804 with any suitable downstream software tools or applications that operate for or in conjunction with the charged-particle microscope 302 (e.g., some embodiments can involve sending the fine boundary localization 804 to such downstream software tools or applications rather than presenting them to the user or technician).

Although the herein disclosure mainly describes various embodiments that are applied to images captured by charged-particle microscopes, these are mere non-limiting examples. In various aspects, various embodiments described herein can be applied to any suitable types of images that are captured or otherwise generated by any suitable types of imaging devices.

In various instances, machine learning algorithms or models can be implemented in any suitable way to facilitate any suitable aspects described herein. To facilitate some of the above-described machine learning aspects of various embodiments, consider the following discussion of artificial intelligence (AI). Various embodiments described herein can employ artificial intelligence to facilitate automating one or more features or functionalities. The components can employ various AI-based schemes for carrying out various embodiments/examples disclosed herein. In order to provide for or aid in the numerous determinations (e.g., determine, ascertain, infer, calculate, predict, prognose, estimate, derive, forecast, detect, compute) described herein, components described herein can examine the entirety or a subset of the data to which it is granted access and can provide for reasoning about or determine states of the system or environment from a set of observations as captured via events or data.

Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events or data.

Such determinations can result in the construction of new events or actions from a set of observed events or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes or systems (e.g., support vector machines, neural networks, expert systems, Bayesian belief networks, fuzzy logic, data fusion engines, and so on) in connection with performing automatic or determined action in connection with the claimed subject matter. Thus, classification schemes or systems can be used to automatically learn and perform a number of functions, actions, or determinations.

A classifier can map an input attribute vector, z=(z₁, z₂, z₃, z₄, zₙ), to a confidence that the input belongs to a class, as by f(z)=confidence(class). Such classification can employ a probabilistic or statistical-based analysis (e.g., factoring into the analysis utilities and costs) to determinate an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, or probabilistic classification models providing different patterns of independence, any of which can be employed. Classification as used herein also is inclusive of statistical regression that is utilized to develop models of priority.

In order to provide additional context for various embodiments described herein, FIG. 18 and the following discussion are intended to provide a brief, general description of a suitable computing environment 1800 in which the various embodiments of the embodiment described herein can be implemented. While the embodiments have been described above in the general context of computer-executable instructions that can run on one or more computers, those skilled in the art will recognize that the embodiments can be also implemented in combination with other program modules or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multi-processor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 18, the example environment 1800 for implementing various embodiments of the aspects described herein includes a computer 1802, the computer 1802 including a processing unit 1804, a system memory 1806 and a system bus 1808. The system bus 1808 couples system components including, but not limited to, the system memory 1806 to the processing unit 1804. The processing unit 1804 can be any of various commercially available processors. Dual microprocessors and other multi-processor architectures can also be employed as the processing unit 1804.

The system bus 1808 can be any of several types of bus structure that can further interconnect to a memory bus (with or without a memory controller), a peripheral bus, and a local bus using any of a variety of commercially available bus architectures. The system memory 1806 includes ROM 1810 and RAM 1812. A basic input/output system (BIOS) can be stored in a non-volatile memory such as ROM, erasable programmable read only memory (EPROM), EEPROM, which BIOS contains the basic routines that help to transfer information between elements within the computer 1802, such as during startup. The RAM 1812 can also include a high-speed RAM such as static RAM for caching data.

The computer 1802 further includes an internal hard disk drive (HDD) 1814 (e.g., EIDE, SATA), one or more external storage devices 1816 (e.g., a magnetic floppy disk drive (FDD) 1816, a memory stick or flash drive reader, a memory card reader, etc.) and a drive 1820, e.g., such as a solid state drive, an optical disk drive, which can read or write from a disk 1822, such as a CD-ROM disc, a DVD, a BD, etc. Alternatively, where a solid state drive is involved, disk 1822 would not be included, unless separate. While the internal HDD 1814 is illustrated as located within the computer 1802, the internal HDD 1814 can also be configured for external use in a suitable chassis (not shown). Additionally, while not shown in environment 1800, a solid state drive (SSD) could be used in addition to, or in place of, an HDD 1814. The HDD 1814, external storage device(s) 1816 and drive 1820 can be connected to the system bus 1808 by an HDD interface 1824, an external storage interface 1826 and a drive interface 1828, respectively. The interface 1824 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 1802, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 1812, including an operating system 1830, one or more application programs 1832, other program modules 1834 and program data 1836. All or portions of the operating system, applications, modules, or data can also be cached in the RAM 1812. The systems and methods described herein can be implemented utilizing various commercially available operating systems or combinations of operating systems.

Computer 1802 can optionally comprise emulation technologies. For example, a hypervisor (not shown) or other intermediary can emulate a hardware environment for operating system 1830, and the emulated hardware can optionally be different from the hardware illustrated in FIG. 18. In such an embodiment, operating system 1830 can comprise one virtual machine (VM) of multiple VMs hosted at computer 1802. Furthermore, operating system 1830 can provide runtime environments, such as the Java runtime environment or the. NET framework, for applications 1832. Runtime environments are consistent execution environments that allow applications 1832 to run on any operating system that includes the runtime environment. Similarly, operating system 1830 can support containers, and applications 1832 can be in the form of containers, which are lightweight, standalone, executable packages of software that include, e.g., code, runtime, system tools, system libraries and settings for an application.

Further, computer 1802 can be enable with a security module, such as a trusted processing module (TPM). For instance with a TPM, boot components hash next in time boot components, and wait for a match of results to secured values, before loading a next boot component. This process can take place at any layer in the code execution stack of computer 1802, e.g., applied at the application execution level or at the operating system (OS) kernel level, thereby enabling security at any level of code execution.

A user can enter commands and information into the computer 1802 through one or more wired/wireless input devices, e.g., a keyboard 1838, a touch screen 1840, and a pointing device, such as a mouse 1842. Other input devices (not shown) can include a microphone, an infrared (IR) remote control, a radio frequency (RF) remote control, or other remote control, a joystick, a virtual reality controller or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 1804 through an input device interface 1844 that can be coupled to the system bus 1808, but can be connected by other interfaces, such as a parallel port, an IEEE 1394 serial port, a game port, a USB port, an IR interface, a BLUETOOTH® interface, etc.

A monitor 1846 or other type of display device can be also connected to the system bus 1808 via an interface, such as a video adapter 1848. In addition to the monitor 1846, a computer typically includes other peripheral output devices (not shown), such as speakers, printers, etc.

The computer 1802 can operate in a networked environment using logical connections via wired or wireless communications to one or more remote computers, such as a remote computer(s) 1850. The remote computer(s) 1850 can be a workstation, a server computer, a router, a personal computer, portable computer, microprocessor-based entertainment appliance, a peer device or other common network node, and typically includes many or all of the elements described relative to the computer 1802, although, for purposes of brevity, only a memory/storage device 1852 is illustrated. The logical connections depicted include wired/wireless connectivity to a local area network (LAN) 1854 or larger networks, e.g., a wide area network (WAN) 1856. Such LAN and WAN networking environments are commonplace in offices and companies, and facilitate enterprise-wide computer networks, such as intranets, all of which can connect to a global communications network, e.g., the Internet.

When used in a LAN networking environment, the computer 1802 can be connected to the local network 1854 through a wired or wireless communication network interface or adapter 1858. The adapter 1858 can facilitate wired or wireless communication to the LAN 1854, which can also include a wireless access point (AP) disposed thereon for communicating with the adapter 1858 in a wireless mode.

When used in a WAN networking environment, the computer 1802 can include a modem 1860 or can be connected to a communications server on the WAN 1856 via other means for establishing communications over the WAN 1856, such as by way of the Internet. The modem 1860, which can be internal or external and a wired or wireless device, can be connected to the system bus 1808 via the input device interface 1844. In a networked environment, program modules depicted relative to the computer 1802 or portions thereof, can be stored in the remote memory/storage device 1852. It will be appreciated that the network connections shown are example and other means of establishing a communications link between the computers can be used.

When used in either a LAN or WAN networking environment, the computer 1802 can access cloud storage systems or other network-based storage systems in addition to, or in place of, external storage devices 1816 as described above, such as but not limited to a network virtual machine providing one or more aspects of storage or processing of information. Generally, a connection between the computer 1802 and a cloud storage system can be established over a LAN 1854 or WAN 1856 e.g., by the adapter 1858 or modem 1860, respectively. Upon connecting the computer 1802 to an associated cloud storage system, the external storage interface 1826 can, with the aid of the adapter 1858 or modem 1860, manage storage provided by the cloud storage system as it would other types of external storage. For instance, the external storage interface 1826 can be configured to provide access to cloud storage sources as if those sources were physically connected to the computer 1802.

The computer 1802 can be operable to communicate with any wireless devices or entities operatively disposed in wireless communication, e.g., a printer, scanner, desktop or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

FIG. 19 is a schematic block diagram of a sample computing environment 1900 with which the disclosed subject matter can interact. The sample computing environment 1900 includes one or more client(s) 1910. The client(s) 1910 can be hardware or software (e.g., threads, processes, computing devices). The sample computing environment 1900 also includes one or more server(s) 1930. The server(s) 1930 can also be hardware or software (e.g., threads, processes, computing devices). The servers 1930 can house threads to perform transformations by employing one or more embodiments as described herein, for example. One possible communication between a client 1910 and a server 1930 can be in the form of a data packet adapted to be transmitted between two or more computer processes. The sample computing environment 1900 includes a communication framework 1950 that can be employed to facilitate communications between the client(s) 1910 and the server(s) 1930. The client(s) 1910 are operably connected to one or more client data store(s) 1920 that can be employed to store information local to the client(s) 1910. Similarly, the server(s) 1930 are operably connected to one or more server data store(s) 1940 that can be employed to store information local to the servers 1930.

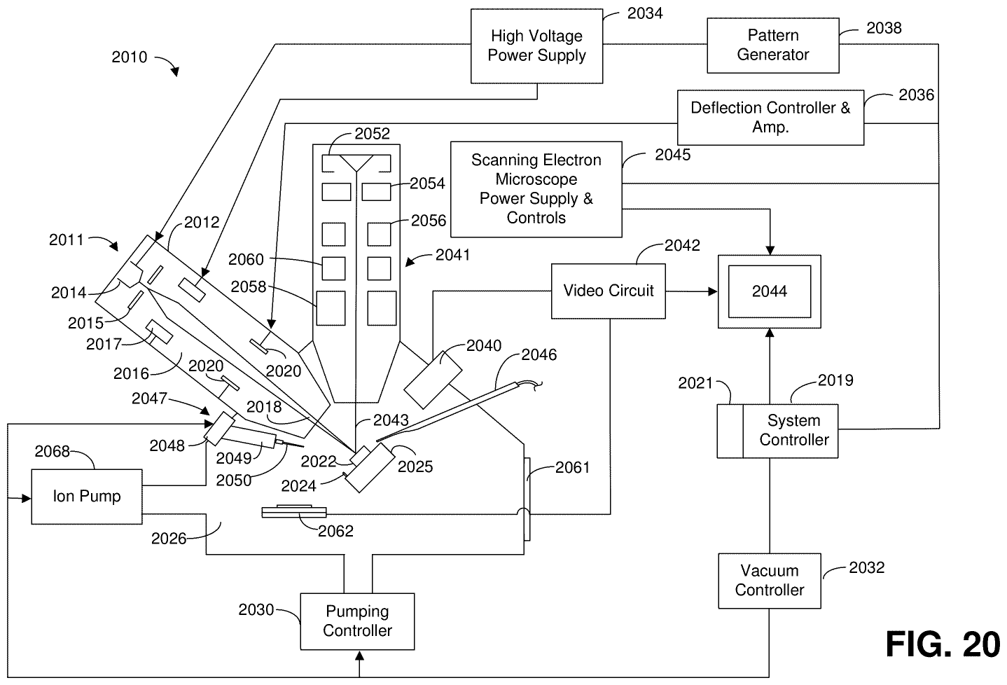

An example, non-limiting apparatus for performing various embodiments described herein is shown in FIG. 20. FIG. 20 illustrates a non-limiting example of a dual beam system 2010 with a vertically mounted scanning electron microscope (SEM) column and a focused ion beam (FIB) column mounted at an angle of approximately 52 degrees from the vertical. Such dual beam systems are commercially available, for example, from FEI Company, Hillsboro, Oregon, the assignee of the present application. While FIG. 20 shows an example of suitable microscopy hardware with which various embodiments described herein can be implemented, it is to be appreciated that such microscopy hardware is non-limiting. In other words, various embodiments described herein can be implemented in conjunction with any other suitable types of microscopy hardware. The dual beam system 2010 is a non-limiting example of the charged-particle microscope 302 or of any other scientific instruments discussed above.

A scanning electron microscope 2041, along with a power supply and control unit 2045, can be provided with the dual beam system 2010. An electron beam 2043 can be emitted from a cathode 2052 by applying voltage between the cathode 2052 and an anode 2054. The electron beam 2043 can be focused to a fine spot by means of a condensing lens 2056 and an objective lens 2058. The electron beam 2043 can be scanned two-dimensionally on any suitable specimen by means of a deflection coil 2060. Operation of the condensing lens 2056, the objective lens 2058, or the deflection coil 2060 can be controlled by the power supply and control unit 2045.

The electron beam 2043 can be focused onto a substrate 2022, which can be on a movable X-Y stage 2025 within a lower chamber 2026. When the electrons in the electron beam 2043 strike the substrate 2022, secondary electrons can be emitted. These secondary electrons can be detected by a secondary electron detector 2040 as discussed below. A scanning transmission electron microscopy (STEM) detector 2062, located beneath a transmission electron microscopy (TEM) sample holder 2024 and the movable X-Y stage 2025, can collect electrons that are transmitted through the sample mounted on the TEM sample holder 2024 as discussed above.

The dual beam system 2010 can also include a focused ion beam (FIB) system 2011 which can comprise an evacuated chamber having an upper neck portion 2012 within which can be located an ion source 2014 and a focusing column 2016 including extractor electrodes and an electrostatic optical system. The axis of the focusing column 2016 can be tilted 52 degrees (or any other suitable angular displacement) from the axis of the electron column. The ion column 2012 can include an ion source 2014, an extraction electrode 2015, a focusing element 2017, deflection elements 2020, and a focused ion beam 2018. The focused ion beam 2018 can pass from the ion source 2014 through the focusing column 2016 and between electrostatic deflection means schematically indicated at numeral 2020 toward the substrate 2022, which can comprise, for example, a semiconductor device positioned on the movable X-Y stage 2025 within the lower chamber 2026.

The movable X-Y stage 2025 can move in a horizontal plane (along X and Y axes) and vertically (along Z axis). The movable X-Y stage 2025 can tilt approximately sixty (60) degrees and rotate about the Z axis. In some embodiments, a separate TEM sample stage (not shown) can be used. Such a TEM sample stage can be moveable in the X, Y, and Z axes. A door 2061 can be opened for inserting the substrate 2022 onto the movable X-Y stage 2025 or also for servicing an internal gas supply reservoir, if one is used. The door 2061 can be interlocked so that it cannot be opened if the system is under vacuum.

An ion pump 2068 can be employed for evacuating the neck portion 2012. The chamber 2026 can be evacuated with a turbomolecular and mechanical pumping system 2030 under the control of a vacuum controller 2032. Such vacuum system can provide within the chamber 2026 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

A high voltage power supply 2034 can provide an appropriate acceleration voltage to electrodes in the focusing column 2016 for energizing and the focused ion beam 2018. When it strikes the substrate 2022, material can be sputtered (that is, physically ejected) from the sample. Alternatively, the focused ion beam 2018 can decompose a precursor gas to deposit a material.

The high voltage power supply 2034 can be connected to the ion source 2014 (which can be a liquid metal ion source) as well as to appropriate electrodes in the ion beam focusing column 2016 for forming an approximately 1 keV to 60 keV ion beam 2018 and directing the same toward a sample. A deflection controller and amplifier 2036, operated in accordance with a prescribed pattern provided by a pattern generator 2038, can be coupled to the deflection elements 2020 (which can be deflection plates) whereby the focused ion beam 2018 may be controlled manually or automatically to trace out a corresponding pattern on the upper surface of the substrate 2022. In some systems, the deflection elements 2020 can be placed before the final lens. Beam blanking electrodes (not shown) within the ion beam focusing column 2016 can cause the focused ion beam 2018 to impact onto a blanking aperture (not shown) instead of the substrate 2022 when a blanking controller (not shown) applies a blanking voltage to a blanking electrode.

The ion source 2014 can provide a metal ion beam of gallium, for example. In other examples, the ion source 2014 may be a plasma ion source that extracts ions from a generated plasma. The source can be capable of being focused into a sub one-tenth micrometer wide beam at the substrate 2022 for either modifying the substrate 2022 by ion milling, enhanced etch, material deposition, or for the purpose of imaging the substrate 2022.

A charged particle detector 2040, such as an Everhart Thornley or multi-channel plate, used for detecting secondary ion or electron emission can be connected to a video circuit 2042 that can supply drive signals to a video monitor 2044 and receive deflection signals from a system controller 2019. The location of the charged particle detector 2040 within the lower chamber 2026 can vary in different embodiments. For example, the charged particle detector 2040 can be coaxial with the ion beam and include a hole for allowing the ion beam to pass. In other embodiments, secondary particles can be collected through a final lens and then diverted off axis for collection.

A micromanipulator 2047 can precisely move objects within the vacuum chamber. The micromanipulator 2047 may comprise precision electric motors 2048 positioned outside the vacuum chamber to provide X, Y, Z, and theta control of a portion 2049 positioned within the vacuum chamber. The micromanipulator 2047 can be fitted with different end effectors for manipulating small objects. In various embodiments described herein, the end effector can be a thin probe 2050.

A gas delivery system 2046 can extend into the lower chamber 2026 for introducing and directing a gaseous vapor toward the substrate 2022. U.S. Pat. No. 5,851,413 to Casella et al. for “Gas Delivery Systems for Particle Beam Processing,” assigned to the assignee of the present invention, describes a suitable gas delivery system 2046. Another gas delivery system is described in U.S. Pat. No. 5,435,850 to Rasmussen for a “Gas Injection System,” also assigned to the assignee of the present invention. For example, iodine can be delivered to enhance etching, or a metal organic compound can be delivered to deposit a metal.

The system controller 2019 can control the operations of the various parts of the dual beam system 2010. Through the system controller 2019, a user can cause the focused ion beam 2018 or the electron beam 2043 to be scanned in a desired manner through commands entered into any suitable user interface (not shown). Alternatively, the system controller 2019 may control the dual beam system 2010 in accordance with programmed instructions stored in a memory 2021. In various embodiments, any of the one or more software components 313 (e.g., the access component 314, the scan component 316, the coarse component 318, the fine component 320) can be implemented in or otherwise executed by the system controller 2019.

Various embodiments may be a system, a method, an apparatus or a computer program product at any possible technical detail level of integration. The computer program product can include a computer readable storage medium (or media) having computer readable program instructions thereon for causing a processor to carry out aspects of various embodiments. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network or a wireless network. The network can comprise copper transmission cables, optical transmission fibers, wireless transmission, routers, firewalls, switches, gateway computers or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of various embodiments can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform various aspects.

Various aspects are described herein with reference to flowchart illustrations or block diagrams of methods, apparatus (systems), and computer program products according to various embodiments. It will be understood that each block of the flowchart illustrations or block diagrams, and combinations of blocks in the flowchart illustrations or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart or block diagram block or blocks. These computer readable program instructions can also be stored in a computer readable storage medium that can direct a computer, a programmable data processing apparatus, or other devices to function in a particular manner, such that the computer readable storage medium having instructions stored therein comprises an article of manufacture including instructions which implement aspects of the function/act specified in the flowchart or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart or block diagram block or blocks.

The flowcharts and block diagrams in the Figures illustrate the architecture, functionality, and operation of possible implementations of systems, methods, and computer program products according to various embodiments. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer or computers, those skilled in the art will recognize that this disclosure also can or can be implemented in combination with other program modules. Generally, program modules include routines, programs, components, data structures, etc. that perform particular tasks or implement particular abstract data types. Moreover, those skilled in the art will appreciate that various aspects can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, or a computer. By way of illustration, both an application running on a server and the server can be a component. One or more components can reside within a process or thread of execution and a component can be localized on one computer or distributed between two or more computers. In another example, respective components can execute from various computer readable media having various data structures stored thereon. The components can communicate via local or remote processes such as in accordance with a signal having one or more data packets (e.g., data from one component interacting with another component in a local system, distributed system, or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. As used herein, the term “and/or” is intended to have the same meaning as “or.” Moreover, articles “a” and “an” as used in the subject specification and annexed drawings should generally be construed to mean “one or more” unless specified otherwise or clear from context to be directed to a singular form. As used herein, the terms “example” or “exemplary” are utilized to mean serving as an example, instance, or illustration. For the avoidance of doubt, the subject matter disclosed herein is not limited by such examples. In addition, any aspect or design described herein as an “example” or “exemplary” is not necessarily to be construed as preferred or advantageous over other aspects or designs, nor is it meant to preclude equivalent exemplary structures and techniques known to those of ordinary skill in the art.

The herein disclosure describes non-limiting examples. For ease of description or explanation, various portions of the herein disclosure utilize the term “each,” “every,” or “all” when discussing various examples. Such usages of the term “each,” “every,” or “all” are non-limiting. In other words, when the herein disclosure provides a description that is applied to “each,” “every,” or “all” of some particular object or component, it should be understood that this is a non-limiting example, and it should be further understood that, in various other examples, it can be the case that such description applies to fewer than “each,” “every,” or “all” of that particular object or component.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM).

Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various non-limiting aspects are described in the following examples.

EXAMPLE 1: A system can comprise: a processor that executes computer-executable components stored in a non-transitory computer-readable memory, wherein the computer-executable components comprise: an access component that can access an image captured by a charged-particle microscope, wherein the image depicts a specimen; a coarse component that can localize, via execution of a deep learning neural network on the image, an approximate boundary of a structure of interest of the specimen; and a fine component that can localize a true boundary of the structure of interest, based on placing a plurality of image processing calipers along the approximate boundary.

EXAMPLE 2: The system of any preceding example can be implemented, wherein each of the plurality of image processing calipers can detect a respective portion of the true boundary based on a respective pixel intensity profile that intersects with the approximate boundary or based on at least one derivative of the respective pixel intensity profile.

EXAMPLE 3: The system of any preceding example can be implemented, wherein a first image processing caliper of the plurality of image processing calipers can detect a first portion of the true boundary based on a denoised, normalized, or otherwise filtered version of a first pixel intensity profile that intersects with the approximate boundary.

EXAMPLE 4: The system of any preceding example can be implemented, wherein a first image processing caliper of the plurality of image processing calipers can correspond to a first pixel intensity profile, wherein a first location along the first pixel intensity profile can correspond to the approximate boundary, and wherein the first location can bisect or be centered on the first pixel intensity profile.

EXAMPLE 5: The system of any preceding example can be implemented, wherein a first image processing caliper of the plurality of image processing calipers can correspond to a first pixel intensity profile, wherein a first location along the first pixel intensity profile can correspond to the approximate boundary, and wherein the first pixel intensity profile can be oriented perpendicularly to the approximate boundary at the first location.

EXAMPLE 6: The system of any preceding example can be implemented, wherein the plurality of image processing calipers can be evenly spaced along the approximate boundary.

EXAMPLE 7: The system of any preceding example can be implemented, wherein a first image processing caliper and a second image processing caliper can be adjacent within the plurality of image processing calipers and can be separated by no intervening pixels.

EXAMPLE 8: The system of any preceding example can be implemented, wherein a first image processing caliper and a second image processing caliper can be adjacent within the plurality of image processing calipers and can be separated by one or more intervening pixels.

EXAMPLE 9: The system of any preceding example can be implemented, wherein the specimen can be a semiconductor sample or a biological sample.

In various embodiments, any combination or combinations of examples 1-9 can be implemented.

EXAMPLE 10: A computer-implemented method can comprise: accessing, by a device operatively coupled to a processor, an image captured by a charged-particle microscope, wherein the image depicts a specimen; localizing, by the device and via execution of a deep learning neural network on the image, an approximate boundary of a structure of interest of the specimen; and localizing, by the device, a true boundary of the structure of interest, based on placing a plurality of image processing calipers along the approximate boundary.

EXAMPLE 11: The computer-implemented method of any preceding example can be implemented, wherein each of the plurality of image processing calipers can detect a respective portion of the true boundary based on a respective pixel intensity profile that intersects with the approximate boundary or based on at least one derivative of the respective pixel intensity profile.

EXAMPLE 12: The computer-implemented method of any preceding example can be implemented, wherein a first image processing caliper of the plurality of image processing calipers can detect a first portion of the true boundary based on a denoised, normalized, or otherwise filtered version of a first pixel intensity profile that intersects with the approximate boundary.

EXAMPLE 13: The computer-implemented method of any preceding example can be implemented, wherein a first image processing caliper of the plurality of image processing calipers can correspond to a first pixel intensity profile, wherein a first location along the first pixel intensity profile can correspond to the approximate boundary, and wherein the first location can bisect or be centered on the first pixel intensity profile.

EXAMPLE 14: The computer-implemented method of any preceding example can be implemented, wherein a first image processing caliper of the plurality of image processing calipers can correspond to a first pixel intensity profile, wherein a first location along the first pixel intensity profile can correspond to the approximate boundary, and wherein the first pixel intensity profile can be oriented perpendicularly to the approximate boundary at the first location.

EXAMPLE 15: The computer-implemented method of any preceding example can be implemented, wherein the plurality of image processing calipers can be evenly spaced along the approximate boundary.

EXAMPLE 16: The computer-implemented method of any preceding example can be implemented, wherein a first image processing caliper and a second image processing caliper can be adjacent within the plurality of image processing calipers and can be separated by no intervening pixels.

EXAMPLE 17: The computer-implemented method of any preceding example can be implemented, wherein a first image processing caliper and a second image processing caliper can be adjacent within the plurality of image processing calipers and can be separated by one or more intervening pixels.

EXAMPLE 18: The computer-implemented method of any preceding example can be implemented, wherein the specimen can be a semiconductor sample or a biological sample.

In various embodiments, any combination or combinations of examples 10-18 can be implemented.

EXAMPLE 19: A computer program product for facilitating edge localization via intelligent insertion of image processing calipers can comprise a non-transitory computer-readable memory having program instructions embodied therewith. In various aspects, the program instructions can be executable by a processor to cause the processor to: instruct a charged-particle microscope to capture a scanned image of a specimen; execute a deep learning edge localizer on the scanned image, thereby yielding a first localization that indicates where in the scanned image a boundary of a structure of interest of the specimen is inferred to be; and generate a second localization that indicates, with higher accuracy than the first localization, where in the scanned image the boundary is, based on placing along the first localization a plurality of image processing calipers that each detect a respective portion of the boundary by analyzing a respective pixel intensity profile that is substantially perpendicular to the first localization.

EXAMPLE 20: The computer program product of any preceding example can be implemented, wherein the plurality of image processing calipers can be evenly distributed around the first localization.

In various embodiments, any combination or combinations of examples 19-20 can be implemented.

In various embodiments, any combination or combinations of examples 1-20 can be implemented.

What is claimed is:

1. A system, comprising:
a processor that executes computer-executable components stored in a non-transitory computer-readable memory, wherein the computer-executable components comprise:
an access component that accesses an image captured by a charged-particle microscope, wherein the image depicts a specimen;
a coarse component that localizes, via execution of a deep learning neural network on the image, an approximate boundary of a structure of interest of the specimen; and
a fine component that localizes a true boundary of the structure of interest, based on placing a plurality of image processing calipers along the approximate boundary.

2. The system of claim 1, wherein each of the plurality of image processing calipers detects a respective portion of the true boundary based on a respective pixel intensity profile that intersects with the approximate boundary or based on at least one derivative of the respective pixel intensity profile.

3. The system of claim 2, wherein a first image processing caliper of the plurality of image processing calipers detects a first portion of the true boundary based on a denoised, normalized, or otherwise filtered version of a first pixel intensity profile that intersects with the approximate boundary.

4. The system of claim 2, wherein a first image processing caliper of the plurality of image processing calipers corresponds to a first pixel intensity profile, wherein a first location along the first pixel intensity profile corresponds to the approximate boundary, and wherein the first location bisects or is centered on the first pixel intensity profile.

5. The system of claim 2, wherein a first image processing caliper of the plurality of image processing calipers corresponds to a first pixel intensity profile, wherein a first location along the first pixel intensity profile corresponds to the approximate boundary, and wherein the first pixel intensity profile is oriented perpendicularly to the approximate boundary at the first location.

6. The system of claim 1, wherein the plurality of image processing calipers are evenly spaced along the approximate boundary.

7. The system of claim 6, wherein a first image processing caliper and a second image processing caliper are adjacent within the plurality of image processing calipers and are separated by no intervening pixels.

8. The system of claim 6, wherein a first image processing caliper and a second image processing caliper are adjacent within the plurality of image processing calipers and are separated by one or more intervening pixels.

9. The system of claim 1, wherein the specimen is a semiconductor sample or a biological sample.

10. A computer-implemented method, comprising:
accessing, by a device operatively coupled to a processor, an image captured by a charged-particle microscope, wherein the image depicts a specimen;
localizing, by the device and via execution of a deep learning neural network on the image, an approximate boundary of a structure of interest of the specimen; and
localizing, by the device, a true boundary of the structure of interest, based on placing a plurality of image processing calipers along the approximate boundary.

11. The computer-implemented method of claim 10, wherein each of the plurality of image processing calipers detects a respective portion of the true boundary based on a respective pixel intensity profile that intersects with the approximate boundary or based on at least one derivative of the respective pixel intensity profile.

12. The computer-implemented method of claim 11, wherein a first image processing caliper of the plurality of image processing calipers detects a first portion of the true boundary based on a denoised, normalized, or otherwise filtered version of a first pixel intensity profile that intersects with the approximate boundary.

13. The computer-implemented method of claim 11, wherein a first image processing caliper of the plurality of image processing calipers corresponds to a first pixel intensity profile, wherein a first location along the first pixel intensity profile corresponds to the approximate boundary, and wherein the first location bisects or is centered on the first pixel intensity profile.

14. The computer-implemented method of claim 11, wherein a first image processing caliper of the plurality of image processing calipers corresponds to a first pixel intensity profile, wherein a first location along the first pixel intensity profile corresponds to the approximate boundary, and wherein the first pixel intensity profile is oriented perpendicularly to the approximate boundary at the first location.

15. The computer-implemented method of claim 10, wherein the plurality of image processing calipers are evenly spaced along the approximate boundary.

16. The computer-implemented method of claim 15, wherein a first image processing caliper and a second image processing caliper are adjacent within the plurality of image processing calipers and are separated by no intervening pixels.

17. The computer-implemented method of claim 15, wherein a first image processing caliper and a second image processing caliper are adjacent within the plurality of image processing calipers and are separated by one or more intervening pixels.

18. The computer-implemented method of claim 10, wherein the specimen is a semiconductor sample or a biological sample.

19. A computer program product for facilitating edge localization via intelligent insertion of image processing calipers, the computer program product comprising a non-transitory computer-readable memory having program instructions embodied therewith, the program instructions executable by a processor to cause the processor to:
instruct a charged-particle microscope to capture a scanned image of a specimen;
execute a deep learning edge localizer on the scanned image, thereby yielding a first localization that indicates where in the scanned image a boundary of a structure of interest of the specimen is inferred to be; and
generate a second localization that indicates, with higher accuracy than the first localization, where in the scanned image the boundary is, based on placing along the first localization a plurality of image processing calipers that each detect a respective portion of the boundary by analyzing a respective pixel intensity profile that is substantially perpendicular to the first localization.

20. The computer program product of claim 19, wherein the plurality of image processing calipers are evenly distributed around the first localization.
